(19) United States
(12) Patent Application Publication
(10) Pub. No.: US 2026/0073978 A1
(43) Pub. Date: Mar. 12, 2026

(54) MEMORY CIRCUIT AND METHOD OF OPERATING THE SAME

(71) Applicant: TAIWAN SEMICONDUCTOR MANUFACTURING COMPANY, LTD., Hsinchu (TW)

(72) Inventors: Haruki MORI, Hsinchu (TW); Je-Min HUNG, Hsinchu (TW); Hidehiro FUJIWARA, Hsinchu (TW); Chia-Fu LEE, Hsinchu (TW); Yu-Der CHIH, Hsinchu (TW); Jonathan Tsung-Yung CHANG, Hsinchu (TW)

(21) Appl. No.: 18/829,560

(22) Filed: Sep. 10, 2024

(51) Int. Cl. G11C 11/419; G06F 7/50; G06F 7/523; G11C 11/412

(52) U.S. Cl. CPC G11C 11/419; G06F 7/50; G06F 7/523; G11C 11/412

(57) ABSTRACT

A memory circuit includes a memory cell array, a multiply-accumulate (MAC) circuit, a first and second driver circuit. The memory cell array is configured to store a first or second set of weight signals. The second set of weight signals is transposed with respect to the first set of weight signals. The MAC circuit is configured to generate a first set of data in response to a set of input data and one of the first or second set of weight signals. The first driver circuit is configured to write the second set of weight signals to the memory cell array in response to being enabled by a first enable signal. The second driver circuit is configured to write the first set of weight signals to the memory cell array in response to being enabled by a second enable signal inverted from the first enable signal.

### BACKGROUND

Recent developments in the field of artificial intelligence have resulted in various products and/or applications, including, but not limited to, speech recognition, image processing, machine learning, natural language processing, or the like. Such products and/or applications often use neural networks to process large amounts of data for learning, training, cognitive computing, or the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a memory device, in accordance with some embodiments.

FIG. 2 is a circuit diagram of a memory circuit, in accordance with some embodiments.

FIG. 3 is a circuit diagram of a memory circuit, in accordance with some embodiments.

FIG. 4A is a circuit diagram of a memory circuit, in accordance with some embodiments.

FIG. 4B is a circuit diagram of a memory cell usable in FIGS. 1, 2, 3 and 4A, in accordance with some embodiments.

FIG. 4C is a circuit diagram of a write driver circuit, in accordance with some embodiments.

FIG. 5A is a circuit diagram of a memory circuit, in accordance with some embodiments.

FIG. 5B is a circuit diagram of a memory cell usable in FIGS. 1, 2, 3 and 5A, in accordance with some embodiments.

FIG. 5C is a circuit diagram of a write driver circuit, in accordance with some embodiments.

FIG. 6A is a diagram of performing a write/read operation in a transpose mode of a memory circuit, in accordance with some embodiments.

FIG. 6B is a diagram of performing a write/read operation in a non-transpose mode of a memory circuit, in accordance with some embodiments.

FIGS. 7A-7B are corresponding graphs of corresponding waveforms, in accordance with some embodiments.

FIG. 8A is a schematic diagram of a memory device, in accordance with some embodiments.

FIG. 8B is a schematic diagram of a neural network, in accordance with some embodiments.

FIG. 8C is a schematic diagram of an integrated circuit (IC) device, in accordance with some embodiments.

FIGS. 9A-9B are a flowchart of a method of operating a circuit, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, a memory circuit includes a memory cell array configured to store a first set of weight signals or a second set of weight signals. In some embodiments, the second set of weight signals is transposed with respect to the first set of weight signals.

In some embodiments, the memory circuit further includes a multiply-accumulate (MAC) circuit coupled to the memory cell array. In some embodiments, the MAC circuit is configured to generate a first set of data in response to a set of input data and one of the first set of weight signals or the second set of weight signals.

In some embodiments, the memory circuit further includes a first driver circuit coupled to the memory cell array. In some embodiments, the first driver circuit is configured to write the second set of weight signals to the memory cell array in response to being enabled by a first enable signal.

In some embodiments, the memory circuit further includes a second driver circuit coupled to the memory cell array. In some embodiments, the second driver circuit is configured to write the first set of weight signals to the memory cell array in response to being enabled by a second enable signal. In some embodiments, the second enable signal is inverted from the first enable signal.

In some embodiments, the first driver circuit is configured to write the second set of weight signals to the memory cell array in a first direction. In some embodiments, the second driver circuit is configured to write the first set of weight signals to the memory cell array in a second direction. In some embodiments, the second direction is different from the first direction.

In some embodiments, the memory cell array includes an array of dual-port memory cells. In some embodiments, each dual-port memory cell of the array of dual-port memory cells is configured as a dual-port memory cell in response to the first driver circuit being enabled, or a single port memory cell in response to the second driver circuit being enabled.

In some embodiments, by configuring each dual-port memory cell of the array of dual-port memory cells to be configured as a dual-port memory cell or a single port memory cell, the memory cell array is configured with bi-directional write capability and thereby achieves better write throughput and MAC throughput than other approaches.

In some embodiments, by configuring the first driver circuit to write the second set of weight signals to the memory cell array in the first direction, and configuring the second driver circuit to write the first set of weight signals to the memory cell array in the second direction, the memory cell array is configured with bi-directional write capability and thereby achieves better write throughput and MAC throughput than other approaches.

In some embodiments, the memory circuit is part of a computing-in-memory (CIM) macro configured to perform CIM operations usable in neural network applications, as well as other applications.

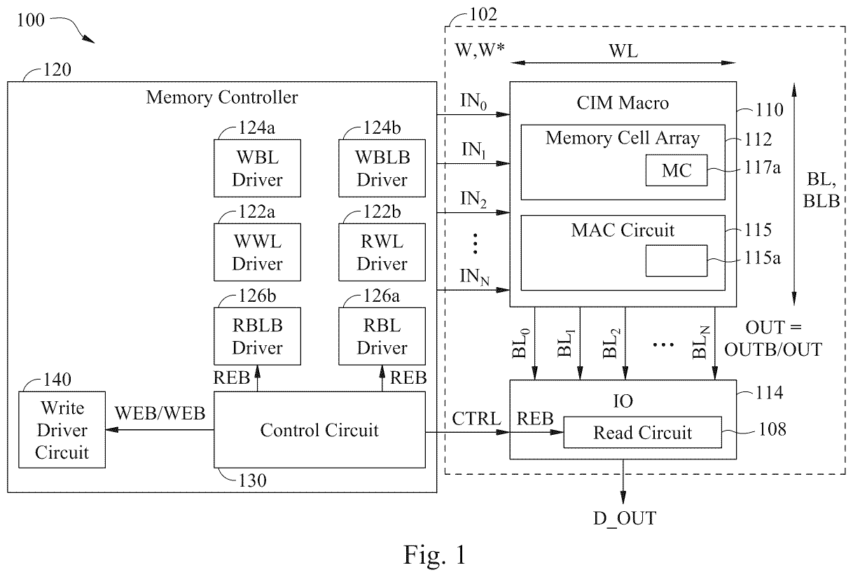

FIG. 1 is a block diagram of a memory device 100, in accordance with some embodiments. A memory device is a type of integrated circuit (IC) device. In at least one embodiment, a memory device is an individual IC device. In some embodiments, a memory device is included as a part of a larger IC device which comprises circuitry other than the memory device for other functionalities.

The memory device 100 comprises a memory circuit 102 and a memory controller 120.

The memory circuit 102 comprises a memory macro 110. The memory macro 110 comprises a memory cell array 112, a multiply-accumulate (MAC) circuit 115 and an input/output (IO) circuit 114. The memory controller 120 comprises a write word line driver 122a, a read word line driver 122b, a write bit line driver 124a, a write bit line bar driver 124b, a read bit line driver 126a, a read bit line bar driver 126b, a control circuit 130 and a write driver circuit 140.

In some embodiments, one or more elements of the memory controller 120 are included in the memory macro 110, and/or one or more elements (except the memory cell array 112) of the memory macro 110 are included in the memory controller 120. In some embodiments, one or more elements of the memory macro 110 are not included in the memory macro 110. In some embodiments, the IO circuit 114 is not included in the memory macro 110.

A macro has a reusable configuration and is usable in various types or designs of IC devices. In some embodiments, the macro is understood in the context of an analogy to the architectural hierarchy of modular programming in which subroutines/procedures are called by a main program (or by other subroutines) to carry out a given computational function. In this context, an IC device uses the macro to perform one or more given functions. Accordingly, in this context and in terms of architectural hierarchy, the IC device is analogous to the main program and the macro is analogous to subroutines/procedures. In some embodiments, the macro is a soft macro. In some embodiments, the macro is a hard macro. In some embodiments, the macro is a soft macro which is described digitally in register-transfer level (RTL) code. In some embodiments, synthesis, placement and routing have yet to have been performed on the macro such that the soft macro can be synthesized, placed and routed for a variety of process nodes. In some embodiments, the macro is a hard macro which is described digitally in a binary file format (e.g., Graphic Database System II (GDSII) stream format), where the binary file format represents planar geometric shapes, text labels, other information or the like of one or more layout-diagrams of the macro in hierarchical form. In some embodiments, synthesis, placement and routing have been performed on the macro such that the hard macro is specific to a particular process node.

A memory macro is a macro comprising memory cells which are addressable to permit data to be written to or read from the memory cells. In some embodiments, a memory macro further comprises circuitry configured to provide access to the memory cells and/or to perform a further function associated with the memory cells. For example, the memory macro 110 comprises memory cells MC, as described herein, that form circuitry configured to provide a computing-in-memory (CIM) function associated with the memory cells MC. In at least one embodiment, a memory macro configured to provide a CIM function is referred to as a CIM macro. The described macro configuration is an example. Other configurations are within the scopes of various embodiments. In some embodiments, the memory cells MC and the MAC circuit 115 are referred to as a “CIM macro.”

The memory cells MC of the memory macro 110 are arranged in a plurality of columns and rows of the memory cell array 112. The memory controller 120 is electrically coupled to the memory cells MC and configured to control operations of the memory cells MC including, but not limited to, a read operation, a write operation, or the like.

The memory cell array 112 further comprises a plurality of word lines (also referred to as “address lines”) WL extending along the rows, a plurality of bit lines (also referred to as “data lines”) BL extending along the columns of the memory cells MC, and a plurality of bit line bars (also referred to as “data line bars”) BLB extending along the columns of the memory cells MC. In some embodiments, the memory cell array 112 does not include the plurality of bit line bars BLB, but further comprises a plurality of source lines SL (not shown) extending along the columns of the memory cells MC. Other variations of memory cell array 112 are within the scope of the present disclosure. Each of the memory cells MC is electrically coupled to the memory controller 120 by at least one of the word lines, at least one of the bit lines and at least one of the bit line bars. In some example operations, word lines are configured for transmitting addresses of the memory cells MC to be read from, or for transmitting addresses of the memory cells MC to be written to, or the like. In at least one embodiment, a set of word lines is configured to perform as both read word lines and write word lines. In some embodiments, bit lines and bit line bars are used for transmitting data read from or written to the memory cells MC indicated by corresponding word lines, or the like.

In some embodiments, read bit lines and/or read bit line bars are configured for transmitting data read from the memory cells MC indicated by corresponding word lines, and write bit lines and/or write bit line bars are configured for transmitting data to be written to the memory cells MC indicated by corresponding word lines, or the like.

The word lines are commonly referred to herein as WL, the bit lines are commonly referred to herein as BL, and the bit line bars are referred to herein as BLB. Various numbers of word lines, bit lines and/or bit line bars in the memory cell array 112 are within the scope of various embodiments. In some embodiments, the memory cells MC are non-volatile memory (NVM). Example memory types of the memory cells MC include, but are not limited to, static random-access memory (SRAM), resistive RAM (RRAM), magnetoresistive RAM (MRAM), phase change RAM (PCRAM), spin transfer torque RAM (STTRAM), floating-gate metal-oxide-semiconductor field-effect transistors (FGMOS), spintronics, or the like. In one or more example embodiments described herein, the memory cells MC include SRAM memory cells.

In some embodiments, in FIG. 1, the memory cells MC are multi-port memory cells. In some embodiments, a port of a memory cell is represented by a set of a word line WL and a bit line BL/bit line bar BLB (referred to herein as a WL/BL/BLB set) which are configured to provide access to the memory cell in a read operation (i.e., read access) and/or in a write operation (i.e., write access). In some embodiments, a multi-port memory cell has several WL/BL/BLB sets each of which is configured for read access only, or for write access only, or for both read access and write access. In some embodiments, in FIG. 1, the memory cells MC are dual-port memory cells.

In some embodiments, in FIG. 1, the memory cells MC are multi-port memory cells that can be configured as multi-port memory cells in response to an enable signal REB or the memory cells MC are multi-port memory cells that can be configured as single port memory cells in response to an enable signal RE. In some embodiments, the enable signal RE is inverted from the enable signal REB. In some embodiments, a single port memory cell has one WL/BL/BLB set which is configured for both read access and write access, but not at the same time.

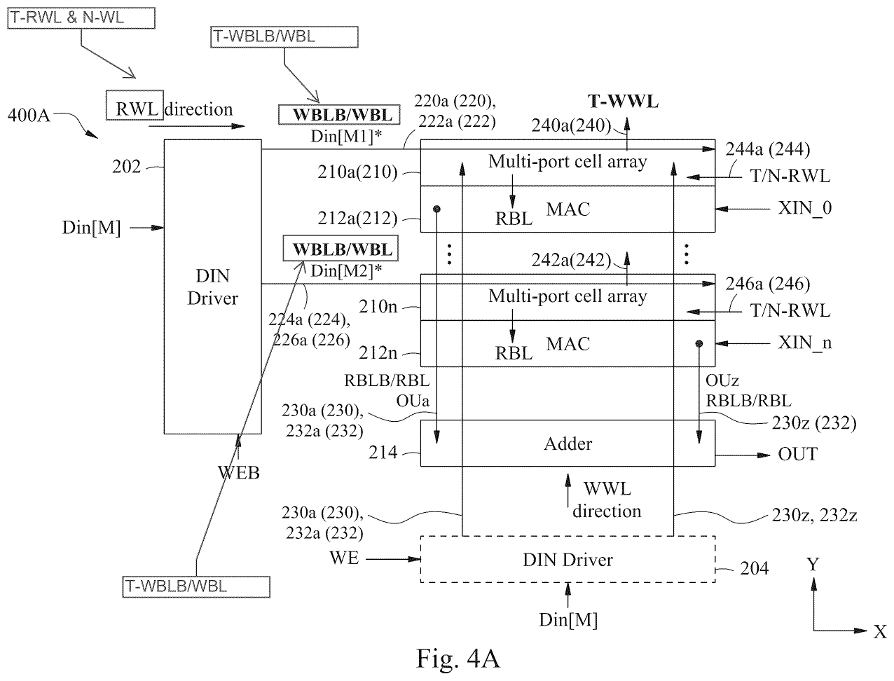

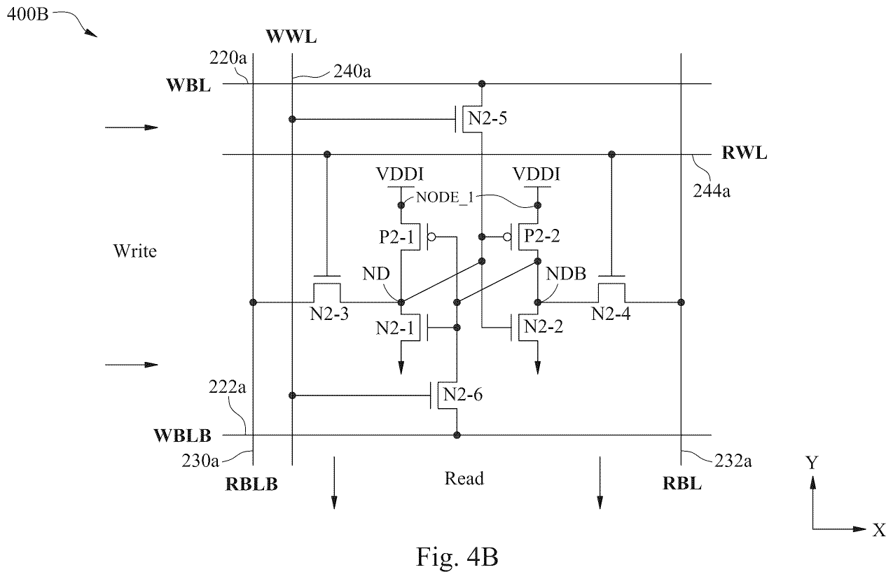

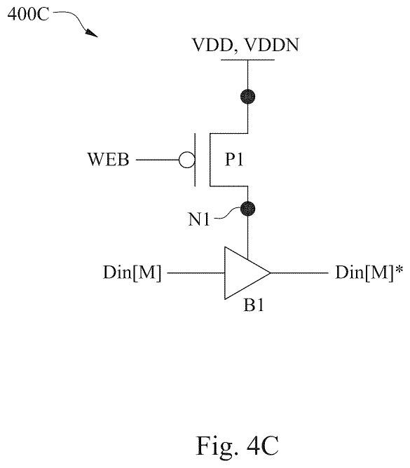

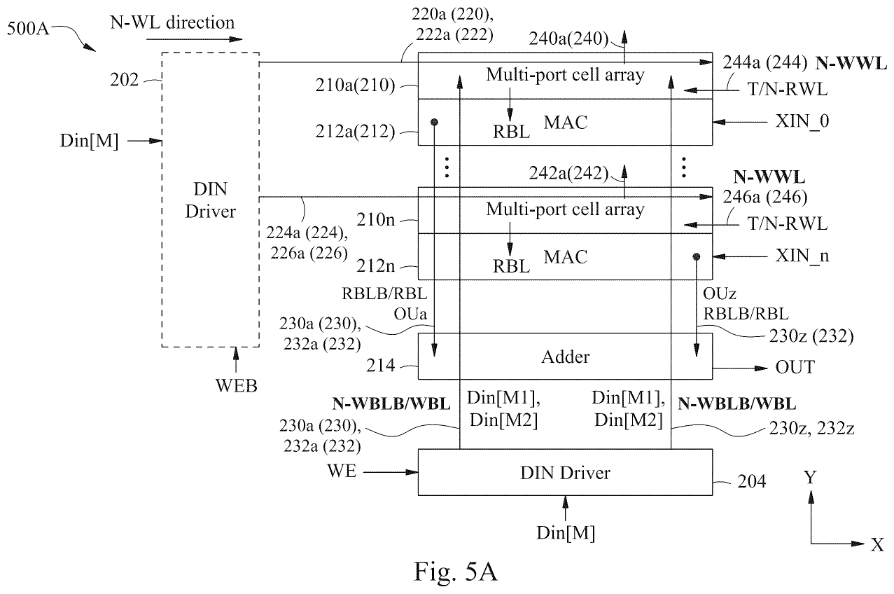

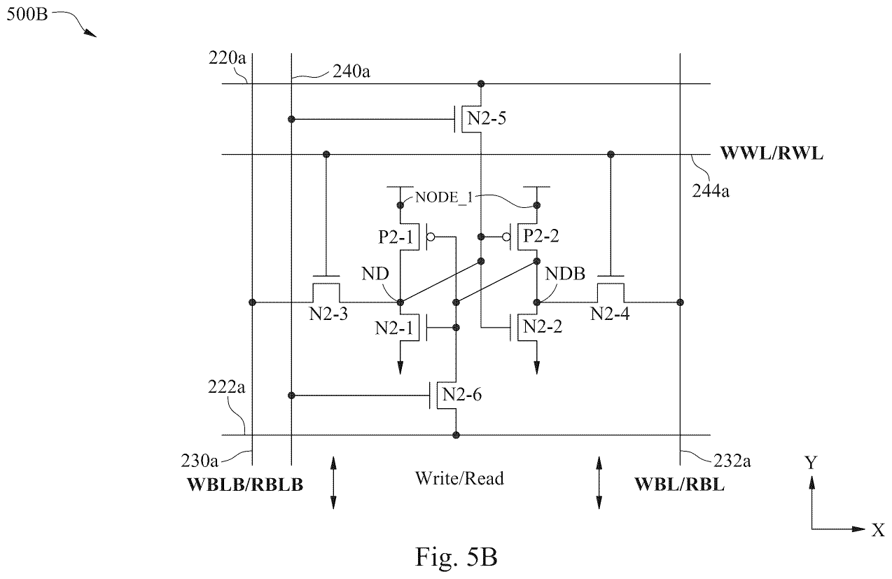

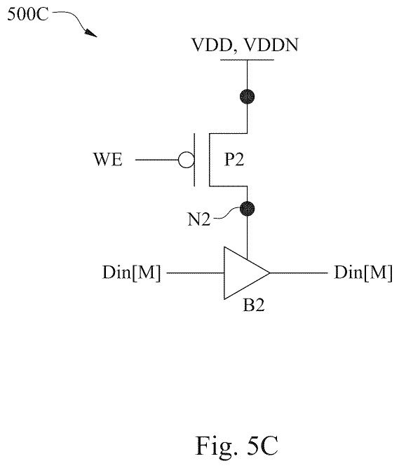

A non-limiting example of a dual-port memory cell is described with respect to FIG. 4B. A non-limiting example of a dual-port memory cell configured as a single port cell is described with respect to FIG. 5B.

Other configurations or other number of ports for memory cells in memory cell array 112 are within the scope of the present disclosure. For example, in some embodiments, one or more memory cells that are described with respect to FIGS. 1-9B can be replaced with a corresponding single port memory cell or multi-port memory cell.

In some embodiments, the memory cell array 112 includes memory cells that store a logic 0 or a logic 1.

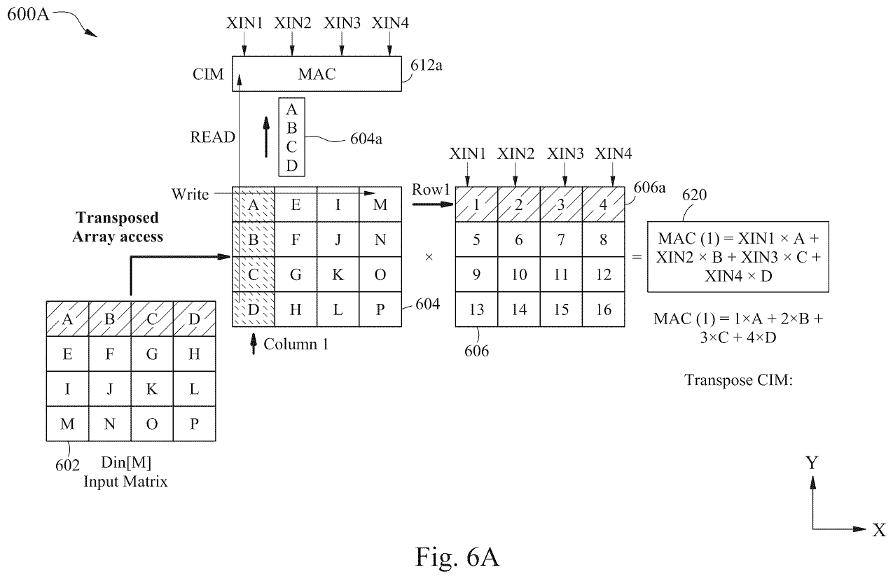

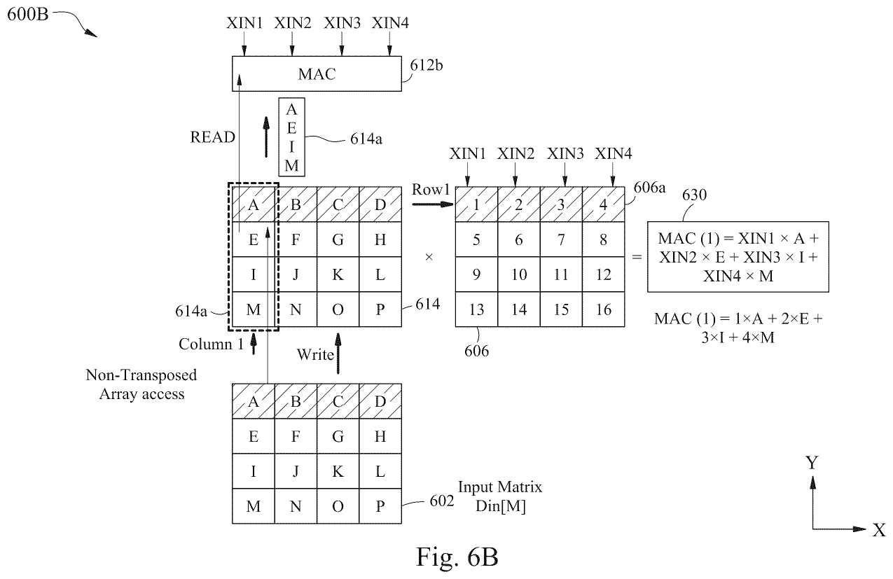

In one or more example embodiments described herein, the memory cells MC are single-bit memory cells, i.e., each memory cell is configured to store a bit of weight data W or transposed weight data W*. In some embodiments, transposed weight data W* is a vector that is transposed with respect to weight data W (shown in FIG. 6A). This is an example, and multi-bit memory cells, each of which is configured to store more than one bit of weight data W or transposed weight data W*, are within the scopes of various embodiments. In some embodiments, a single-bit memory cell is also referred to as a bitcell.

A combination of multiple pieces of weight data W (or transposed weight data W*) stored in multiple memory cells constitutes a weight value to be used in a CIM operation by MAC circuit 115. For simplicity, a piece of weight data stored in a memory cell MC, multiple pieces of weight data stored in multiple memory cells MC, or all pieces of weight data stored in all memory cells MC of the memory cell array 112 are referred to herein as weight data W.

The MAC circuit 115 comprises MAC cells (shown only as a single MAC cell 115a for ease of illustration). In some embodiments, each MAC cell of the MAC cells is a corresponding computation portion 115a of a plurality of computation portions 115a. In some embodiments, each computation portion 115a of the plurality of computation portions 115a is a corresponding MAC element.

Each of the memory cells MC includes a storage portion 117a (shown only in memory cell 117 for ease of illustration) and a computation portion 115a (shown only in memory cell 117 for ease of illustration). Each of the memory cells MC is configured to store a piece of weight data W, and is configured to perform a CIM operation on the piece of weight data W and a piece of received data IN. Each storage portion 117a corresponds to each computation portion 115a. In some embodiments, the received data IN includes received data IN₀, IN₁, . . . , IN_{N}.

Each storage portion 117a of the memory cells MC is configured to store a piece of weight data W or transposed weight data W*, and each computation portion 115a of the memory cells MC is configured to perform a CIM operation on the piece of weight data W or transposed weight data W* and a piece of received data IN.

Each of the MAC cells of MAC circuit 115 includes a computation portion 115a (shown only in a first column of MAC circuit 115 for ease of illustration). Each of the MAC cells of MAC circuit 115 is configured to perform a CIM operation on one of the piece of weight data W or the piece of transposed weight data W* and a piece of received data IN. Each computation portion 115a of MAC circuit 115 is configured to perform a CIM operation on one of the piece of weight data W or the piece of transposed weight data W* and a piece of received data IN. Each computation portion 115a corresponds to each storage portion 117a.

In some embodiments, each computation portion 115a of MAC circuit 115 is coupled to each corresponding memory cell of memory cells MC by a corresponding bit line BL and bit line bar BLB, and is configured to receive one of weight data W or transposed weight data W*.

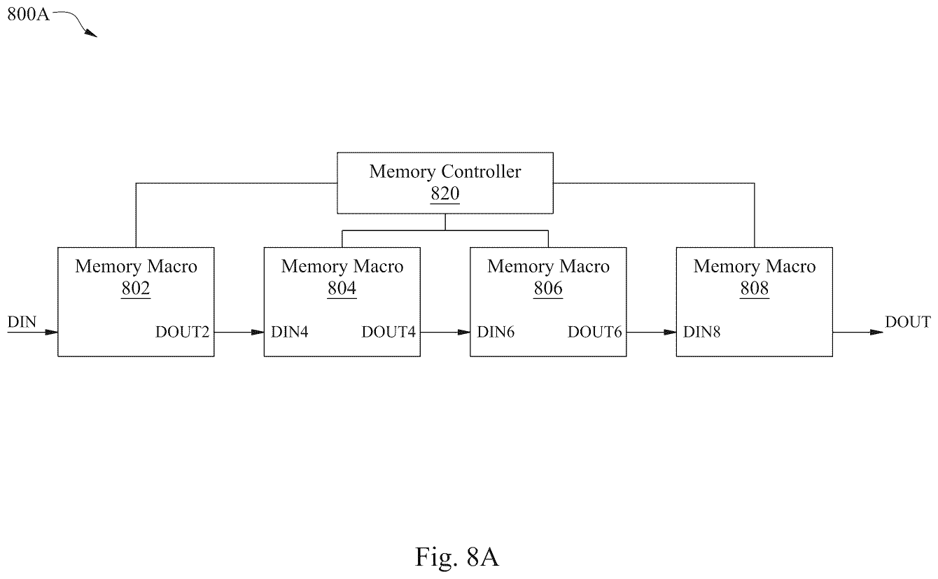

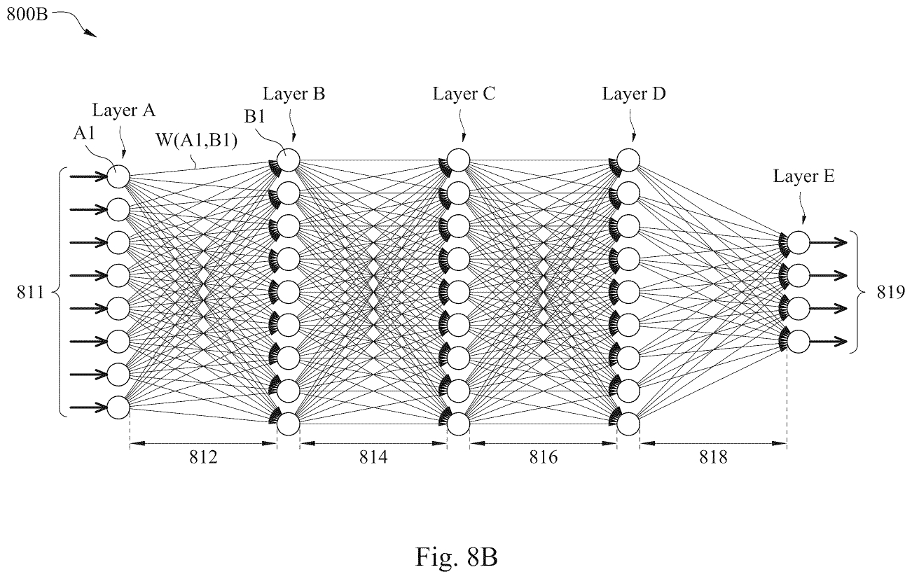

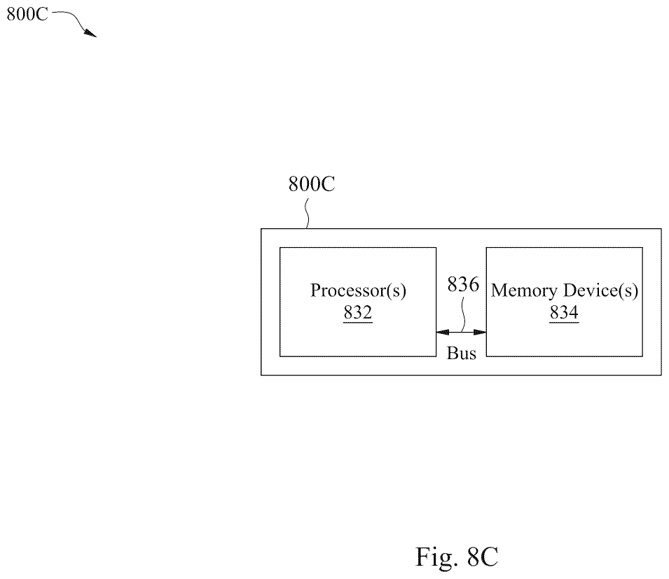

Each computation portion 115a of MAC circuit 115 is configured to receive input data IN. In the example configuration in FIG. 1, the input data IN are supplied from the memory controller 120. In one or more embodiments, the input data IN are output data (e.g., output data D_OUT) supplied from another memory macro (not shown) of the memory device 100 as shown in FIG. 8A. In some embodiments, the input data IN are serially supplied to the computation portion 115a in the form of a stream of bits, as described herein.

The computation portion 115a of MAC circuit 115 is configured to, based on the input data IN, to generate output data OUT or OUTB corresponding to a CIM operation performed on the input data IN and one of the weight data W or transposed weight data W* read from one or more of the memory cells MC. Examples of CIM operations include, but are not limited to, mathematical operations, logical operations, combination thereof, or the like. In at least one embodiment, the computation portion 115a is a MAC circuit, and the CIM operation comprises a multiplication of one or more multibit weight values with one or more multibit input data values. Further computation portions or circuits configured to perform CIM operations other than a multiplication are within the scopes of various embodiments. The output data OUT or OUTB are supplied, as input data, to the IO circuit 114.

In one or more example embodiments described herein, each computation portion 115a is configured to compute a corresponding bit of an output signal OUT or OUTB based on a CIM operation of one of the bit of weight data W or transposed weight data W* and a bit of received data IN. This is an example, and when the memory cells MC are multi-bit memory cells, each of which is configured to store more than one bit of weight data W or transposed weight data W*, then each computation portion 115a is configured to perform a corresponding CIM operation on the corresponding multi-bit pieces of weight data W or transposed weight data W* thereby generating corresponding bits of the output signal OUT or OUTB (also referred to as a “set of data signals OUT or OUTB”or a “set of data OUT or OUTB”), and are within the scopes of various embodiments.

The IO circuit 114 has inputs coupled to the bit lines BL/bit line bars BLB to receive the output data OUT/OUTB from one or more of the memory cells MC by the MAC circuit 115. In some embodiments, the IO circuit 114 is configured to receive the output data OUT/OUTB from the memory cell array 112 received from the bit lines BL/bit line bars BLB, and to generate the output signal D_OUT (also referred to as a “set of output signals D_OUT”) on an output of the IO circuit 114.

In some embodiments, the IO circuit 114 is configured to receive a set of control signals CTRL from the control circuit 130. In some embodiments, the set of control signals CTRL includes at least one of a read enable signal REB, a write enable signal WEB or a write enable signal WE. In some embodiments, the write enable signal WE is inverted from the write enable signal WEB and vice versa.

In some embodiments, the IO circuit 114 includes a read circuit 108. In some embodiments, the read circuit 108 is configured to receive the read enable signal REB from the control circuit 130. In some embodiments, the read circuit 108 is configured to be enabled or disabled in response to the read enable signal REB. In some embodiments, the read circuit 108 of the IO circuit 114 is configured to perform a read operation of memory macro 110 in response to being enabled by the read enable signal REB. In some embodiments, the read circuit 108 of the IO circuit 114 is configured to not perform a read operation of memory macro 110 in response to being disabled by the read enable signal REB. In some embodiments, the read circuit 108 includes one or more sense amplifiers. Examples of the IO circuit 114 include registers, flip-flops, latches, or the like.

In some embodiments, the output data D_OUT are supplied, as input data, to another memory macro (not shown) of the memory device 100 (as shown in FIG. 8A). In one or more embodiments, the output data D_OUT are output, through one or more I/O circuits (not shown) of the memory controller 120, to external circuitry outside the memory device 100, for example, a processor as described herein.

In the example configuration in FIG. 1, the controller 120 comprises the write word line driver 122a, the read word line driver 122b, the write bit line driver 124a, the write bit line bar driver 124b, the read bit line driver 126a, the read bit line bar driver 126b, the control circuit 130 and the write driver circuit 140.

In at least one embodiment, the controller 120 further includes one or more clock generators for providing clock signals for various components of the memory device 100, one or more input/output (I/O) circuits for data exchange with external devices, and/or one or more controllers for controlling various operations in the memory device 100.

The write driver circuit 140 is coupled to the memory cell array 112. In some embodiments, write driver circuit 140 is coupled to the memory cell array 112 by a set of write bit lines WBL and a set of write bit line bars WBLB. The write driver circuit 140 is configured to receive at least one of the write enable signal WEB or the write enable signal WE from the control circuit 130. In some embodiments, the write driver 140 is configured to perform a write operation of memory macro 110 in response to the write enable signal WEB or the write enable signal WE. In some embodiments, the write driver 140 is configured to write the transposed weight data W* to the memory cell array 112 in response to the write enable signal WEB or the write driver 140 is configured to write the weight data W to the memory cell array 112 in response to the write enable signal WE.

In some embodiments, by configuring the write driver 140 to write the transposed weight data W* to the memory cell array 112 in response to the write enable signal WEB or by configuring the write driver 140 to write the weight data W to the memory cell array 112 in response to the write enable signal WE results in a more flexible design than other approaches.

In some embodiments, by configuring the write driver 140 to write the transposed weight data W* to the memory cell array 112, a first number of clock cycles used to write a first amount of information is lower than a second number of clock cycles used to write the first amount of information thereby causing memory device 100 to achieve better write throughput and MAC throughput than other approaches.

In some embodiments, by configuring the write driver 140 to write the transposed weight data W* to the memory cell array 112, memory device 100 is configured to use less buffers than other approaches, thereby resulting in less area than other approaches.

The write word line driver 122a is configured to decode a row address of the memory cell MC selected to be accessed in a write operation. The write word line driver 122a is configured to supply a voltage to the selected write word line WWL corresponding to the decoded row address, and a different voltage to the other, unselected write word lines WWL. In some embodiments, each write word line WWL1, WWL2, . . . , WWLr of write word lines WWL has a corresponding input signal IN₀, IN₁, . . . , INᵣ of the input signal IN.

The write word line driver 122a is coupled to the memory cell array 112 via the write word lines WWL. The write word line driver 122a is configured to decode a row address of the memory cell MC selected to be accessed in a write operation. The write word line driver 122a is configured to supply a voltage to the selected write word line WWL corresponding to the decoded row address, and a different voltage to the other, unselected write word lines WWL. In some embodiments, each write word line WWL1, WWL2, . . . , WWLr of write word lines WWL has a corresponding input signal IN₀, IN₁, . . . , INᵣ of the input signal IN.

The read word line driver 122b is coupled to the memory cell array 112 via the read word lines RWL. The read word line driver 122b is configured to decode a row address of the memory cell MC selected to be accessed in a read operation. The read word line driver 122b is configured to supply a voltage to the selected read word line RWL corresponding to the decoded row address, and a different voltage to the other, unselected read word lines RWL. In some embodiments, each read word line RWL1, RWL2, . . . , RWLr of word lines WL has a corresponding read word line signal.

The write bit line driver 124a is coupled to the memory cell array 112 via the write bit lines WBL. The write bit line driver 124a is configured to decode a column address of the memory cell MC selected to be accessed in a write operation. The write bit line driver 124a is configured to supply a voltage to the selected write bit line WBL corresponding to the decoded column address, and a different voltage to the other, unselected write bit lines WBL.

The write bit line bar driver 124b is coupled to the memory cell array 112 via the write bit line bars WBLB. The write bit line bar driver 124b is configured to decode a column address of the memory cell MC selected to be accessed in a write operation. The write bit line bar driver 124b is configured to supply a voltage to the selected write bit line bar WBLB corresponding to the decoded column address, and a different voltage to the other, unselected write bit line bars WBLB.

The read bit line driver 126a is coupled to the memory cell array 112 via the read bit lines RBL. The read bit line driver 126a is configured to decode a column address of the memory cell MC selected to be accessed in a read operation. The read bit line driver 126a is configured to supply a voltage to the selected read bit line RBL corresponding to the decoded column address, and a different voltage to the other, unselected read bit lines RBL.

The read bit line bar driver 126b is coupled to the memory cell array 112 via the read bit line bars RBLB. The read bit line bar driver 126b is configured to decode a column address of the memory cell MC selected to be accessed in a read operation. The read bit line bar driver 126b is configured to supply a voltage to the selected read bit line bar RBLB corresponding to the decoded column address, and a different voltage to the other, unselected read bit line bars RBLB.

The control circuit 130 is configured to generate the set of control signals CTRL. In some embodiments, the set of control signals CTRL includes at least one of the write enable signal WEB, the write enable signal WE or the read enable signal REB. In some embodiments, the control circuit 130 is configured to generate at least one of the write enable signal WEB, the write enable signal WE or the read enable signal REB.

The control circuit 130 is coupled to one or more of the memory cells MC, MAC circuit 115, IO circuit 114, write word line driver 122a, read word line driver 122b, write bit line driver 124a, write bit line bar driver 124b, read bit line driver 126a, read bit line bar driver 126b, read circuit 108 or write driver circuit 140, to coordinate operations of these circuits, and/or drivers in the overall operation of the memory device 100. For example, the control circuit 130 is configured to generate various control signals for controlling operations of one or more of the memory cells MC, MAC circuit 115, IO circuit 114, write word line driver 122a, read word line driver 122b, write bit line driver 124a, write bit line bar driver 124b, read bit line driver 126a, read bit line bar driver 126b, read circuit 108 or write driver circuit 140.

The write driver circuit 140 is configured to receive at least one of the write enable signal WEB or the write enable signal WE from the control circuit 130.

The control circuit 130 is configured to receive the input data from external circuitry outside the memory device 100, for example, a processor as described herein. The input data are received through one or more I/O circuits (such as IO circuit 114), and are forwarded by the control circuit 130 to the memory cell array 112.

In at least one embodiment, CIM memory devices, such as the memory device 100, are advantageous over other approaches, where data are moved back and forth between the memory and a processor, because such back-and-forth data movement, which is a bottleneck to both performance and energy efficiency, is avoidable. Examples of CIM applications include, but are not limited to, artificial intelligence, image recognition, neural network for machine learning, or the like. In some embodiments, the memory device 100 makes it possible to simultaneously perform weight data updating and CIM operations, in one or more embodiments.

As a result, in at least one embodiment, it is possible to achieve one or more advantages including, but not limited to, reduced processing time, reduced power consumption, reduced chip area, lowered manufacturing cost, improved performance, or the like.

Other configurations or quantities of elements in memory device 100 are within the scope of the present disclosure.

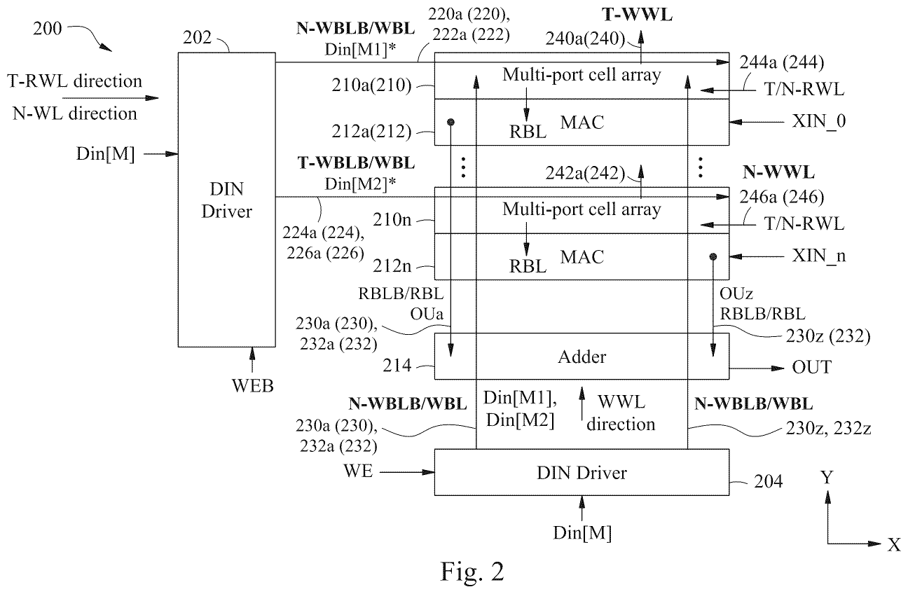

FIG. 2 is a circuit diagram of a memory circuit 200, in accordance with some embodiments.

Memory circuit 200 is an embodiment of portions of memory device 100 of FIG. 1, and similar detailed description is therefore omitted.

Components that are the same or similar to those in one or more of FIGS. 1, 2, 3, 4A-4C, 5A-5C, 6A-6B, 7A-7B and 8A-8C (shown below) are given the same reference numbers, and detailed description thereof is thus omitted. For ease of illustration, some of the labeled elements of FIGS. 1, 2, 3, 4A-4C, 5A-5C, 6A-6B, 7A-7B and 8A-8C are not labelled in each of FIGS. 1, 2, 3, 4A-4C, 5A-5C, 6A-6B, 7A-7B and 8A-8C. In some embodiments, FIGS. 1, 2, 3, 4A-4C, 5A-5C, 6A-6B, 7A-7B and 8A-8C include additional elements not shown in FIGS. 1, 2, 3, 4A-4C, 5A-5C, 6A-6B, 7A-7B and 8A-8C.

Memory circuit 200 includes a write driver circuit 202, a write driver circuit 204, a set of memory cell arrays 210, a set of MAC circuits 212, and an adder circuit 214.

In some embodiments, the set of memory cell arrays 210 is memory cell array 112 of FIG. 1, the set of MAC circuits 212 is MAC circuit 115 of FIG. 1, and similar detailed description is therefore omitted.

In some embodiments, at least one of write driver circuit 202 or write driver circuit 204 is an embodiment of write driver circuit 140 of FIG. 1, and similar detailed description is therefore omitted.

In some embodiments, adder circuit 214 is part of MAC circuit 115 of FIG. 1, and similar detailed description is therefore omitted. In some embodiments, adder circuit 214 is an embodiment of IO circuit 114 of FIG. 1, and similar detailed description is therefore omitted.

At least one of write driver circuit 202 or write driver circuit 204 is coupled to the set of memory cells 210.

Write driver circuit 202 is configured to receive weight signals Din[M] and the write enable signal WEB. In some embodiments, the weight signals Din[M] is weight data W of FIG. 1, and similar detailed description is therefore omitted. In some embodiments, transposed weight signals Din[M]* is transposed weight data W* of FIG. 1, and similar detailed description is therefore omitted. In some embodiments, the transposed weight signals Din[M]* is a vector that is transposed with respect to the weight signals Din[M].

In some embodiments, the weight signals Din[M] is divided into portions of weight signals, such as weight signals Din[M1] and weight signals Din[M2]. In some embodiments, integer M is equal to a sum of integer M1 and integer M2. Integer M1 and M2 correspond to a number of portions that weight signals Din[M] is divided into. Other values for the number of portions that weight signals Din[M] is divided into are within the scope of the present disclosure. In some embodiments, the weight signals Din[M] includes at least one of weight signals Din[M1] or weight signals Din[M2].

In some embodiments, the transposed weight signals Din[M]* is divided into portions of transposed weight signals, such as transposed weight signals Din[M1]* and transposed weight signals Din[M2]*. In some embodiments, integer M1 and M2 correspond to a number of portions that transposed weight signals Din[M]* is divided into. Other values for the number of portions that transposed weight signals Din[M]* is divided into are within the scope of the present disclosure. In some embodiments, the transposed weight signals Din[M]* includes at least one of transposed weight signals Din[M1]* or transposed weight signals Din[M2]*.

In some embodiments, the transposed weight signal Din[M1]* is a vector that is transposed with respect to the weight signal Din[M1]. In some embodiments, the transposed weight signal Din[M2]* is a vector that is transposed with respect to the weight signal Din[M2].

The write driver circuit 202 is coupled to the set of memory cell arrays 210. In some embodiments, the write circuit 202 is configured to be enabled or disabled in response to the write enable signal WEB. In some embodiments, the write driver circuit 202 is configured to write the transposed weight signals Din[M]* to the set of memory cell arrays 210 in response to being enabled by the write enable signal WEB. In some embodiments, if the write driver circuit 202 is disabled by the write enable signal WEB, then the write driver circuit 202 configured to not write the transposed weight signals Din[M]* to the set of memory cell arrays 210.

In some embodiments, the write driver circuit 202 is coupled to each memory cell array 210a, . . . , 210n of the set of memory cell arrays 210, and is configured to write the transposed weight signals Din[M1]*, Din[M2]* to corresponding memory cell array 210a, . . . , 210n of the set of memory cell arrays 210 in response to being enabled by the write enable signal WEB.

Write driver circuit 204 is configured to receive weight signal Din[M] and the write enable signal WE. The write driver circuit 204 is coupled to the set of memory cell arrays 210. In some embodiments, the write circuit 204 is configured to be enabled or disabled in response to the write enable signal WE. In some embodiments, the write driver circuit 204 is configured to write the weight signals Din[M] to the set of memory cell arrays 210 in response to being enabled by the write enable signal WE. In some embodiments, if the write driver circuit 204 is disabled by the write enable signal WE, then the write driver circuit 204 configured to not write the weight signals Din[M] to the set of memory cell arrays 210.

In some embodiments, the write driver circuit 204 is coupled to each memory cell array 210a, . . . , 210n of the set of memory cell arrays 210, and is configured to write the weight signals Din[M1], Din[M2] to corresponding memory cell array 210a, . . . , 210n of the set of memory cell arrays 210 in response to being enabled by the write enable signal WE.

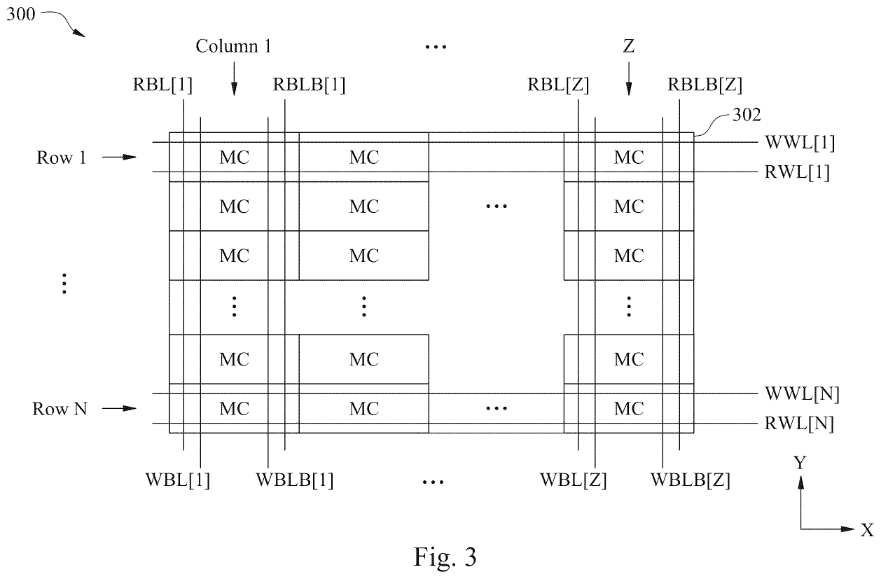

The set of memory cell arrays 210 comprises at least one or more of memory cell array 210a, . . . , 210n, where n is an integer corresponding to the number of memory cell arrays in the set of memory cell arrays 210. In some embodiments, one or more of memory cell arrays 210a, . . . , 210n of the set of memory cell arrays 210 is memory cell array 300 of FIG. 3, similar detailed description is therefore omitted.

The set of memory cell arrays 210 is coupled to the write driver circuit 202, the write driver circuit 204, the set of MAC circuits 212.

The set of memory cell arrays 210 is configured to store weight signals Din[M] or the transposed weight signals Din[M]*. In some embodiments, the set of memory cell arrays 210 is configured to store the transposed weight signals Din[M]* or the weight signals Din[M] based on the corresponding write enable signal WEB or write enable signal WE.

In some embodiments, the set of memory cell arrays 210 is configured as a multi-port memory cell in response to the write driver circuit 202 being enabled by the write enable signal WEB, or the set of memory cell arrays 210 is configured as a single port memory cell in response to the write driver circuit 204 being enabled by the write enable signal WE. In some embodiments, the set of memory cell arrays 210 is configured as a dual-port memory cell in response to the write driver circuit 202 being enabled by the write enable signal WEB, or the set of memory cell arrays 210 is configured as a single port memory cell in response to the write driver circuit 204 being enabled by the write enable signal WE.

Each memory cell array 210a, . . . , 210n of the set of memory cell arrays 210 is coupled to the write driver circuit 202, the write driver circuit 204, and a corresponding MAC circuit 212a, . . . , 212n of the set of MAC circuits 212.

Memory cell array 210a is configured to store weight signals Din[M1] or transposed weight signals Din[M1]*. In some embodiments, memory cell array 210a is configured to store weight signals Din[M1] or transposed weight signals Din[M1]* based on the corresponding write enable signal WEB or write enable signal WE.

In some embodiments, memory cell array 210a is configured as a multi-port memory cell in response to the write driver circuit 202 being enabled by the write enable signal WEB, or memory cell array 210a is configured as a single port memory cell in response to the write driver circuit 204 being enabled by the write enable signal WE. In some embodiments, memory cell array 210a is configured as a dual-port memory cell in response to the write driver circuit 202 being enabled by the write enable signal WEB, or memory cell arrays 210a is configured as a single port memory cell in response to the write driver circuit 204 being enabled by the write enable signal WE.

Memory cell array 210n is configured to store weight signals Din[M2] or transposed weight signals Din[M2]*. In some embodiments, memory cell array 210n is configured to store weight signals Din[M2] or transposed weight signals Din[M2]* based on the corresponding write enable signal WEB or write enable signal WE.

In some embodiments, memory cell array 210n is configured as a multi-port memory cell in response to the write driver circuit 202 being enabled by the write enable signal WEB, or memory cell array 210n is configured as a single port memory cell in response to the write driver circuit 204 being enabled by the write enable signal WE. In some embodiments, memory cell array 210n is configured as a dual-port memory cell in response to the write driver circuit 202 being enabled by the write enable signal WEB, or memory cell arrays 210n is configured as a single port memory cell in response to the write driver circuit 204 being enabled by the write enable signal WE.

The set of MAC circuits 212 comprises at least one or more of MAC circuits 212a, . . . , 212n, where n is an integer corresponding to the number of MAC circuits in the set of MAC circuits 212. In some embodiments, one or more of MAC circuits 212a, . . . , 212n of the set of MAC circuits 212 is MAC circuit 115 of FIG. 1, similar detailed description is therefore omitted. In some embodiments, the set of memory cell arrays 210 and the set of MAC circuits 212 are referred to as a “CIM macro.”

The set of MAC circuits 212 is coupled to the set of memory cell arrays 210 and the adder circuit 214.

The set of MAC circuits 212 is configured to receive a set of input data XIN. The set of MAC circuits 212 is configured to retrieve one of weight signals Din[M] or transposed weight signals Din[M]*. The set of MAC circuits 212 is configured to generate a set of data OU in response to the set of input data XIN and one of one of weight signals Din[M] or transposed weight signals Din[M]*. In some embodiments, the set of MAC circuits 212 is configured to generate the set of data OU based on a CIM operation between the set of input data XIN and one of weight signals Din[M] or transposed weight signals Din[M]*.

In some embodiments, the set of input data XIN comprises one or more of input data XIN_0, . . . , XIN_n, where n is an integer corresponding to the number of input data in the set of input data Xin.

In some embodiments, the set of data OU comprises one or more of data OUa, . . . , OUz, where z is an integer corresponding to the number of columns of data in the set of data OU.

Each MAC circuit 212a, . . . , 212n of the set of MAC circuits 212 is coupled to the adder circuit 214, and a corresponding memory cell array 210a, . . . , 210n of the set of memory cell arrays 210.

MAC circuit 212a is coupled to the memory cell array 210a, and configured to generate data OUa of the set of data OU in response to input data XIN_0 of the set of input data XIN and one of weight signals Din[M1] or transposed weight signals Din[M1]*. In some embodiments, MAC circuit 212a is configured to generate data OUa in response to input data XIN_0 of the set of input data XIN and one of weight signals Din[M1] or transposed weight signals Din[M1]* based on the corresponding write enable signal WEB or write enable signal WE.

MAC circuit 212n is coupled to the memory cell array 210a, and configured to generate data OUz of the set of data OU in response to input data XIN_0 of the set of input data XIN and one of weight signals Din[M1] or transposed weight signals Din[M1]*. In some embodiments, MAC circuit 212n is configured to generate data OUz in response to input data XIN_n of the set of input data XIN and one of weight signals Din[M2] or transposed weight signals Din[M2]* based on the corresponding write enable signal WEB or write enable signal WE.

The adder circuit 214 is coupled to the set of MAC circuits 214, and is configured to generate a set of output signals OUT in response to the set of data OU. In some embodiments, the set of data OUT comprises one or more of output data OUTa, . . . , OUz, where z is an integer corresponding to the number of columns of data in the set of output data OUT.

In some embodiments, the adder circuit 214 is coupled to at least one of MAC circuit 214a, . . . , 214n of the set of MAC circuits. In some embodiments, the adder circuit 214 is configured to generate the set of output signals OUT in response to the data OUa of the set of data OU, . . . , data OUz of the set of data OU.

In some embodiments, read circuit 108 of FIG. 1 is coupled to memory cell array 210a and MAC circuit 212a, and is configured to read memory cell array 210a in response to being enabled by the read enable signal REB. In some embodiments, read circuit 108 of FIG. 1 is coupled to memory cell array 210n and MAC circuit 212n, and is configured to read memory cell array 210n in response to being enabled by the read enable signal REB. In some embodiments, the read circuit 108 is configured to perform the read operation of the memory cell array 210a and memory cell array 210n in the second direction Y.

Memory circuit 200 further includes a set of conductors 220, a set of conductors 222, a set of conductors 224, a set of conductors 226, a set of conductors 230, a set of conductors 232, a set of conductors 240, a set of conductors 242, a set of conductors 244 and a set of conductors 246.

The set of conductors 220 extends in the first direction X. The set of conductors 220 comprises at least one or more of conductors 220a, . . . , 220n, where n is an integer corresponding to the number of conductors in the set of conductors 220.

In some embodiments, the set of conductors 220 electrically couples the write driver circuit 202 and memory cell array 210a of the set of memory cell arrays 210 together. In some embodiments, each conductor 220a, . . . , 220n of the set of conductors 220 is electrically coupled to a corresponding row of memory cells of memory cell array 210a.

In some embodiments, if the write driver circuit 202 is enabled by the write enable signal WEB, then the write driver circuit 202 is electrically coupled to the memory cell array 210a by the set of conductors 220, the set of conductors 220 is configured as the set of write bit lines WBL of memory cell array 210a, each memory cell array of the memory cell array 210a is configured as a dual-port memory cell (as shown in FIG. 4B), and the memory cell array 210a is configured to store transposed weight signals Din[M1]* during one or more write operations.

The set of conductors 222 extends in the first direction X. The set of conductors 222 comprises at least one or more of conductors 222a, . . . , 222n, where n is an integer corresponding to the number of conductors in the set of conductors 222.

In some embodiments, the set of conductors 222 electrically couples the write driver circuit 202 and memory cell array 210a of the set of memory cell arrays 210 together. In some embodiments, each conductor 222a, . . . , 222n of the set of conductors 222 is electrically coupled to a corresponding row of memory cells of memory cell array 210a.

In some embodiments, if the write driver circuit 202 is enabled by the write enable signal WEB, then the write driver circuit 202 is electrically coupled to the memory cell array 210a by the set of conductors 222, the set of conductors 222 is configured as the set of write bit line bars WBLB of memory cell array 210a, each memory cell array of the memory cell array 210a is configured as a dual-port memory cell (as shown in FIG. 4B), and the memory cell array 210a is configured to store transposed weight signals Din[M1]* during one or more write operations.

The set of conductors 224 extends in the first direction X. The set of conductors 224 comprises at least one or more of conductors 224a, . . . , 224n, where n is an integer corresponding to the number of conductors in the set of conductors 224.

In some embodiments, the set of conductors 224 electrically couples the write driver circuit 202 and memory cell array 210n of the set of memory cell arrays 210 together. In some embodiments, each conductor 224a, . . . , 224n of the set of conductors 224 is electrically coupled to a corresponding row of memory cells of memory cell array 210n.

In some embodiments, if the write driver circuit 202 is enabled by the write enable signal WEB, then the write driver circuit 202 is electrically coupled to the memory cell array 210n by the set of conductors 224, the set of conductors 224 is configured as the set of write bit lines WBL of memory cell array 210a, each memory cell array of the memory cell array 210n is configured as a dual-port memory cell (as shown in FIG. 4B), and the memory cell array 210n is configured to store transposed weight signals Din[M1]* during one or more write operations.

The set of conductors 226 extends in the first direction X. The set of conductors 226 comprises at least one or more of conductors 226a, . . . , 226n, where n is an integer corresponding to the number of conductors in the set of conductors 226.

In some embodiments, the set of conductors 226 electrically couples the write driver circuit 202 and memory cell array 210n of the set of memory cell arrays 210 together. In some embodiments, each conductor 226a, . . . , 226n of the set of conductors 226 is electrically coupled to a corresponding row of memory cells of memory cell array 210n.

In some embodiments, if the write driver circuit 202 is enabled by the write enable signal WEB, then the write driver circuit 202 is electrically coupled to the memory cell array 210 by the set of conductors 226, the set of conductors 226 is configured as the set of write bit line bars WBLB of memory cell array 210n, each memory cell array of the memory cell array 210n is configured as a dual-port memory cell (as shown in FIG. 4B), and the memory cell array 210n is configured to store transposed weight signals Din[M1]* during one or more write operations.

The set of conductors 230 extends in the second direction Y. The set of conductors 230 comprises at least one or more of conductors 230a, . . . , 230z, where n is an integer corresponding to the number of conductors in the set of conductors 230.

In some embodiments, the set of conductors 230 electrically couples at least one of memory cell array 210a or memory cell array 210n and the write driver circuit 204 together. In some embodiments, each conductor 230a, . . . , 230z of the set of conductors 230 is electrically coupled to at least one of a corresponding column of memory cells of memory cell array 210a or a corresponding column of memory cells of memory cell array 210n.

In some embodiments, if the write driver circuit 204 is enabled by the write enable signal WE, then the write driver circuit 204 is electrically coupled to memory cell array 210a by the set of conductors 230, the set of conductors 230 is configured as the set of write bit line bars WBLB of memory cell array 210a, each memory cell array of the memory cell array 210a is configured as a single port memory cell (as shown in FIG. 5B), and the memory cell array 210a is configured to store weight signals Din[M1] during one or more write operations.

In some embodiments, if the write driver circuit 204 is enabled by the write enable signal WE, then the write driver circuit 204 is electrically coupled to memory cell array 210n by the set of conductors 230, the set of conductors 230 is configured as the set of write bit line bars WBLB of memory cell array 210a, each memory cell array of the memory cell array 210n is configured as a single port memory cell (as shown in FIG. 5B), and the memory cell array 210n is configured to store weight signals Din[M2] during one or more write operations.

The set of conductors 232 extends in the second direction Y. The set of conductors 232 comprises at least one or more of conductors 232a, . . . , 232z, where n is an integer corresponding to the number of conductors in the set of conductors 232.

In some embodiments, the set of conductors 232 electrically couples at least one of memory cell array 210a or memory cell array 210n and the write driver circuit 204 together. In some embodiments, each conductor 232a, . . . , 232z of the set of conductors 232 is electrically coupled to at least one of a corresponding column of memory cells of memory cell array 210a or a corresponding column of memory cells of memory cell array 210n.

In some embodiments, if the write driver circuit 204 is enabled by the write enable signal WE, then the write driver circuit 204 is electrically coupled to memory cell array 210a by the set of conductors 232, the set of conductors 232 is configured as the set of write bit lines WBL of memory cell array 210a, each memory cell array of the memory cell array 210a is configured as a single port memory cell (as shown in FIG. 5B), and the memory cell array 210a is configured to store weight signals Din[M1] during one or more write operations.

In some embodiments, if the write driver circuit 204 is enabled by the write enable signal WE, then the write driver circuit 204 is electrically coupled to memory cell array 210n by the set of conductors 232, the set of conductors 232 is configured as the set of write bit lines WBL of memory cell array 210a, each memory cell array of the memory cell array 210n is configured as a single port memory cell (as shown in FIG. 5B), and the memory cell array 210n is configured to store weight signals Din[M2] during one or more write operations.

The set of conductors 240 extends in the second direction Y. The set of conductors 240 comprises at least one or more of conductors 240a, . . . , 240z, where n is an integer corresponding to the number of conductors in the set of conductors 240.

In some embodiments, the set of conductors 240 electrically couples at least one of memory cell array 210a and the WWL driver circuit 122a together. In some embodiments, each conductor 240a, . . . , 240z of the set of conductors 240 is electrically coupled to at least one of a corresponding column of memory cells of memory cell array 210a.

In some embodiments, if the write driver circuit 202 is enabled by the write enable signal WEB, then each memory cell array of the memory cell array 210a is configured as a dual-port memory cell (as shown in FIG. 4B), the memory cell array 210a is configured to store transposed weight signals Din[M1]* during one or more write operations, and the set of conductors 240 is configured as the set of write word bit lines WWL of memory cell array 210a.

The set of conductors 242 extends in the second direction Y. The set of conductors 242 comprises at least one or more of conductors 242a, . . . , 242z, where n is an integer corresponding to the number of conductors in the set of conductors 242.

In some embodiments, the set of conductors 242 electrically couples at least one of memory cell array 210n and the WWL driver circuit 122a together. In some embodiments, each conductor 242a, . . . , 242z of the set of conductors 242 is electrically coupled to at least one of a corresponding column of memory cells of memory cell array 210n.

In some embodiments, if the write driver circuit 202 is enabled by the write enable signal WEB, then each memory cell array of the memory cell array 210n is configured as a dual-port memory cell (as shown in FIG. 4B), the memory cell array 210n is configured to store transposed weight signals Din[M1]* during one or more write operations, and the set of conductors 242 is configured as the set of write word bit lines WWL of memory cell array 210n.

The set of conductors 244 extends in the first direction X. The set of conductors 244 comprises at least one or more of conductors 244a, . . . , 244n, where n is an integer corresponding to the number of conductors in the set of conductors 244.

In some embodiments, the set of conductors 244 electrically couples at least one of memory cell array 210a and the RWL driver circuit 122b together. In some embodiments, each conductor 244a, . . . , 244n of the set of conductors 244 is electrically coupled to at least one of a corresponding row of memory cells of memory cell array 210a.

In some embodiments, the set of conductors 244 is configured as the set of read word lines RWL of memory cell array 210a. In some embodiments, the set of conductors 244 is configured as the set of read word lines RWL of memory cell array 210a.

In some embodiments, if the write driver circuit 202 is enabled by the write enable signal WE, then each memory cell array of the memory cell array 210a is configured as a single port memory cell (as shown in FIG. 5B), the memory cell array 210a is configured to store weight signals Din[M1] during one or more write operations, and the set of conductors 244 is configured as the set of write word lines WWL of memory cell array 210a.

In some embodiments, if the write driver circuit 202 is enabled by the write enable signal WE, then each memory cell array of the memory cell array 210n is configured as a single port memory cell (as shown in FIG. 5B), the memory cell array 210n is configured to store weight signals Din[M2] during one or more write operations, and the set of conductors 244 is configured as the set of write word lines WWL of memory cell array 210n.

The set of conductors 246 extends in the first direction X. The set of conductors 246 comprises at least one or more of conductors 246a, . . . , 246n, where n is an integer corresponding to the number of conductors in the set of conductors 246.

In some embodiments, the set of conductors 246 electrically couples at least one of memory cell array 210n and the WWL driver circuit 122a together. In some embodiments, each conductor 246a, . . . , 246n of the set of conductors 246 is electrically coupled to at least one of a corresponding row of memory cells of memory cell array 210n.

In some embodiments, the set of conductors 246 is configured as the set of read word lines RWL of memory cell array 210a. In some embodiments, the set of conductors 246 is configured as the set of read word lines RWL of memory cell array 210n.

In some embodiments, if the write driver circuit 202 is enabled by the write enable signal WE, then each memory cell array of the memory cell array 210a is configured as a single port memory cell (as shown in FIG. 5B), the memory cell array 210a is configured to store weight signals Din[M1] during one or more write operations, and the set of conductors 246 is configured as the set of write word bit lines WWL of memory cell array 210a.

In some embodiments, if the write driver circuit 202 is enabled by the write enable signal WE, then each memory cell array of the memory cell array 210n is configured as a single port memory cell (as shown in FIG. 5B), the memory cell array 210n is configured to store weight signals Din[M2] during one or more write operations, and the set of conductors 246 is configured as the set of write word bit lines WWL of memory cell array 210n.

In some embodiments, by configuring the write driver circuit 202 to write the transposed weight signals Din[M]* to the memory cell array 112 in response to the write enable signal WEB or by configuring the write driver 104 to write the weight signals Din[M] to the memory cell array 210 in response to the write enable signal WE results in a more flexible design than other approaches.

In some embodiments, by configuring the write driver circuit 202 to write the transposed weight signals Din[M]* to the memory cell array 210, a first number of clock cycles used to write a first amount of information is lower than a second number of clock cycles used to write the first amount of information thereby causing memory circuit 200 to achieve better write throughput and MAC throughput than other approaches.

In some embodiments, by configuring the write driver circuit 202 to write the transposed weight signals Din[M]* to the memory cell array 210, memory circuit 200 is configured to use less buffers than other approaches, thereby resulting in less area than other approaches.

In some embodiments, by configuring each dual-port memory cell of the memory cell array 210 to be configured as a dual-port memory cell or a single port memory cell, the memory cell array 210 is configured with bi-directional write capability and thereby achieves better write throughput and MAC throughput than other approaches, and is a more flexible design than other approaches.

In some embodiments, by configuring the write driver circuit 202 to write the transposed weight signals Din[M]* to the memory cell array 210 in the first direction X, and configuring the write driver circuit 204 to write the weight signals Din[M] to the memory cell array 210 in the second direction Y, the memory cell array 210 is configured with bi-directional write capability and thereby achieves better write throughput and MAC throughput than other approaches.

Other configurations or quantities of elements in memory circuit 200 are within the scope of the present disclosure.

FIG. 3 is a circuit diagram of a memory circuit 300, in accordance with some embodiments.

Memory circuit 300 is an embodiment of memory cell array 112 of FIG. 1, and similar detailed description is therefore omitted.

Memory circuit 300 comprises a memory cell array 302 having M rows and N columns of memory cells MC, where N is a positive integer corresponding to the number of columns in memory cell array 302 and M is a positive integer corresponding to the number of rows in memory cell array 302. In some embodiments, each memory cell MC is a corresponding storage portion 117a of FIG. 1, and similar detailed description is therefore omitted. The rows of cells in memory cell array 302 are arranged in the first direction X. The columns of cells in memory cell array 302 are arranged in the second direction Y.

In some embodiments, each memory cell MC in memory cell array 302 is configured to store a bit of data. In some embodiments, memory circuit 300 is logic based memory.

The number of rows M in memory cell array 302 is equal to or greater than 1. The number of columns N in memory cell array 302 is equal to or greater than 1. Different types of memory cells MC in memory cell array 302 are within the contemplated scope of the present disclosure.

Memory circuit 300 further comprises Z write bit lines BL[1], . . . BL[Z] (collectively referred to as “write bit line WBL”). Each column 1, . . . , Z in memory cell array 302 is overlapped and coupled to a corresponding write bit line WBL[1], . . . , WBL[Z]. Each write bit line WBL extends in the second direction Y and over a column of cells (e.g., column 1, . . . , Z). In some embodiments, each write bit line WBL extends in the first direction X and over a row of cells (e.g., row 1, . . . , N).

Memory circuit 300 further comprises Z write bit line bars WBLB[1], . . . WBLB[Z] (collectively referred to as “write bit line bar WBLB”). Each column 1, . . . , Z in memory cell array 302 is overlapped and coupled to a corresponding write bit line bar WBLB[1], . . . , WBLB[Z]. Each write bit line bar WBLB extends in the second direction Y and over a column of cells (e.g., column 1, . . . , Z). In some embodiments, each write bit line bar WBLB extends in the first direction X and over a row of cells (e.g., row 1, . . . , N).

Memory circuit 300 further comprises N write word lines WWL[1], . . . WWL[N] (collectively referred to as “write word line WWL”). Each row 1, . . . , N in memory cell array 302 is overlapped and coupled to a corresponding write word line WWL[1], . . . , WWL[N]. Each write word line WWL extends in the first direction X and over a row of cells (e.g., row 1, . . . , N). In some embodiments, each write word line WWL extends in the second direction Y and over a column of cells (e.g., row 1, . . . , Z).

Memory circuit 300 further comprises N read word lines RWL[1], . . . RWL[N] (collectively referred to as “read word line RWL”). Each row 1, . . . , N in memory cell array 302 is overlapped and coupled to a corresponding read word line RWL[1], . . . , RWL[N]. Each read word line RWL extends in the first direction X and over a row of cells (e.g., row 1, . . . , N). In some embodiments, each read word line RWL extends in the second direction Y and over a column of cells (e.g., row 1, . . . , Z).

In some embodiments, memory circuit 300 achieves one or more of the benefits discussed herein.

Other configurations of memory circuit 300 are within the scope of the present disclosure. In some embodiments, one or more of write bit lines WBL, write bit line bars WBLB, read bit lines RBL, read bit line bars RBLB, write word lines WWL or read word lines RWL are not included in memory circuit 300. In some embodiments, one or more of write bit lines WBL, write bit line bars WBLB, read bit lines RBL, read bit line bars RBLB, write word lines WWL or read word lines RWL are replaced with a corresponding source line SL. In some embodiments, one or more source lines SL is added.

FIG. 4A is a circuit diagram of a memory circuit 400A, in accordance with some embodiments.

Memory circuit 400A is an embodiment of portions of memory device 100 of FIG. 1, and similar detailed description is therefore omitted.

In some embodiments, memory circuit 400A is a non-limiting example of write driver circuit 202 being enabled by the write enable signal WEB, and similar detailed description is therefore omitted. In some embodiments, memory circuit 400A is configured to operate in a “transpose mode” since the write driver circuit 202 is configured to write the transposed weight signals Din[M]* to the set of memory cell arrays 210 in response to being enabled by the write enable signal WEB.

In some embodiments, memory circuit 400A is memory circuit 200 of FIG. 2, and similar detailed description is therefore omitted.

Memory circuit 400A includes write driver circuit 202, write driver circuit 204, set of memory cell arrays 210, set of MAC circuits 212 and adder circuit 214.

In some embodiments, the write driver circuit 202 is configured to write the transposed weight signals Din[M]* to the set of memory cell arrays 210 in response to being enabled by the write enable signal WEB.

In some embodiments, the write driver circuit 202 is configured to write the transposed weight signals Din[M1]*, Din[M2]* to corresponding memory cell array 210a, . . . , 210n of the set of memory cell arrays 210 in response to being enabled by the write enable signal WEB.

In some embodiments, memory cell array 210a is configured as a dual-port memory cell in response to the write driver circuit 202 being enabled by the write enable signal WEB.

In some embodiments, memory cell array 210n is configured as a dual-port memory cell in response to the write driver circuit 202 being enabled by the write enable signal WEB.

In some embodiments, as shown in FIG. 4A, since the write driver circuit 202 is enabled by the write enable signal WEB, then the write driver circuit 202 is electrically coupled to the memory cell array 210a by the set of conductors 220, and the set of conductors 220 is configured as the set of write bit lines WBL of memory cell array 210a, and each memory cell array of the memory cell array 210a is configured as a dual-port memory cell (as shown in FIG. 4B), and the memory cell array 210a is configured to store transposed weight signals Din[M1]* during one or more write operations.

In some embodiments, as shown in FIG. 4A, since the write driver circuit 202 is enabled by the write enable signal WEB, then the write driver circuit 202 is electrically coupled to the memory cell array 210a by the set of conductors 222, and the set of conductors 222 is configured as the set of write bit line bars WBLB of memory cell array 210a, each memory cell array of the memory cell array 210a is configured as a dual-port memory cell (as shown in FIG. 4B), and the memory cell array 210a is configured to store transposed weight signals Din[M1]* during one or more write operations.

In some embodiments, as shown in FIG. 4A, since the write driver circuit 202 is enabled by the write enable signal WEB, then the write driver circuit 202 is electrically coupled to the memory cell array 210n by the set of conductors 224, and the set of conductors 224 is configured as the set of write bit lines WBL of memory cell array 210a, and each memory cell array of the memory cell array 210n is configured as a dual-port memory cell (as shown in FIG. 4B), and the memory cell array 210n is configured to store transposed weight signals Din[M2]* during one or more write operations.

In some embodiments, as shown in FIG. 4A, since the write driver circuit 202 is enabled by the write enable signal WEB, then the write driver circuit 202 is electrically coupled to the memory cell array 210n by the set of conductors 226, and the set of conductors 226 is configured as the set of write bit line bars WBLB of memory cell array 210a, each memory cell array of the memory cell array 210n is configured as a dual-port memory cell (as shown in FIG. 4B), and the memory cell array 210n is configured to store transposed weight signals Din[M2]* during one or more write operations.

In some embodiments, the write driver circuit 202 is configured to perform the write operation of the transposed weight signals Din[M]* in the first direction X. In some embodiments, the write driver circuit 202 is configured to perform the write operation of the transposed weight signals Din[M1]* in the first direction X. In some embodiments, the write driver circuit 202 is configured to perform the write operation of the transposed weight signals Din[M2]* in the first direction X.

In some embodiments, the set of conductors 220 is configured as the set of write bit lines WBL of memory cell array 210a. In some embodiments, the set of conductors 222 is configured as the set of write bit line bars WBLB of memory cell array 210a.

In some embodiments, the set of conductors 224 is configured as the set of write bit lines WBL of memory cell array 210n. In some embodiments, the set of conductors 226 is configured as the set of write bit line bars WBLB of memory cell array 210n.

In some embodiments, the set of conductors 244 is configured as the set of read word lines RWL of memory cell array 210a. In some embodiments, the set of conductors 246 is configured as the set of read word lines RWL of memory cell array 210n. In some embodiments, the set of read word lines RWL in FIG. 4A extends in the first direction X.

In some embodiments, the set of conductors 244 is configured as the set of write word lines WWL of memory cell array 210a. In some embodiments, the set of conductors 244 is configured as the set of write word lines WWL of memory cell array 210n. In some embodiments, the set of write word lines WWL in FIG. 4A extends in the second direction Y.

In some embodiments, memory circuit 400A achieves one or more of the benefits discussed herein.

Other configurations or quantities of elements in memory circuit 400A are within the scope of the present disclosure.

FIG. 4B is a circuit diagram of a memory cell 400B usable in FIGS. 1, 2, 3 and 4A, in accordance with some embodiments.

Memory cell 400B is usable as one or more memory cells MC in at least one of memory cell array 112 of FIG. 1.

Memory cell 400B is usable as one or more memory cells MC in at least one memory cell array in the set of memory cell arrays 210 of FIG. 4A, and similar detailed description is therefore omitted.

Memory cell 400B is usable as one or more memory cells MC in at least one memory cell in memory cell arrays 302 of FIG. 3, and similar detailed description is therefore omitted.

Memory cell 400B is a six transistor (8T) dual-port (DP) SRAM memory cell used for illustration. In some embodiments, memory cell 400B employs a number of transistors other than eight. Other types of memory are within the scope of various embodiments.

Memory cell 400B comprises two P field effect transistors (PFET) transistors P2-1 and P2-2, and six NFET transistors N2-1, N2-2, N2-3, N2-4, N2-5 and N2-6. PFET transistors P2-1 and P2-2, and NFET transistors N2-1 and N2-2 form a cross latch or a pair of cross-coupled inverters. For example, PFET transistor P2-1 and NFET transistor N2-1 form a first inverter, while PFET transistor P2-2 and NFET transistor N2-2 form a second inverter.

A source terminal of each of PFET transistors P2-1 and P2-2 is configured as a voltage supply node NODE_1. Each voltage supply node NODE_1 is coupled to a first voltage supply VDDI.

Each of a drain terminal of PFET transistor P2-1, a drain terminal of NFET transistor N2-1, a gate terminal of PFET transistor P2-2, a gate terminal of NFET transistor N2-2, a source terminal of NFET transistor N2-3 and a drain/source terminal of NFET transistor N2-5 are coupled together, and are configured as a storage node ND.

Each of a drain terminal of PFET transistor P2-2, a drain terminal of NFET transistor N2-2, a gate terminal of PFET transistor P2-1, a gate terminal of NFET transistor N2-1, a source terminal of NFET transistor N2-4 and a drain/source terminal of NFET transistor N2-6 are coupled together, and are configured as a storage node NDB.

A source terminal of each of NFET transistors N2-1 and N2-2 is configured as a supply reference voltage node (not labelled) having a supply reference voltage VSS. The source terminal of each of NFET transistors N2-1 and N2-2 is also coupled to reference voltage supply VSS.

A source/drain terminal of NFET transistor N2-5 is coupled to conductor 220a of the set of conductors 220. In some embodiments, conductor 220a of the set of conductors 220 is configured as the write bit line WBL, and the source/drain terminal of NFET transistor N2-5 is coupled to the write bit line WBL.

A source/drain terminal of NFET transistor N2-6 is coupled to conductor 222a of the set of conductors 222. In some embodiments, conductor 222a of the set of conductors 222 is configured as the write bit line bar WBLB, and the source/drain terminal of NFET transistor N2-6 is coupled to the write bit line bar WBLB.

A gate terminal of each of NFET transistors N2-3 and N2-4 is coupled to conductor 244a of the set of conductors 244. In some embodiments, conductor 244a of the set of conductors 244 is configured as the read word line RWL, and the gate terminal of each of NFET transistors N2-3 and N2-4 is coupled to the read word line RWL.

A gate terminal of each of NFET transistors N2-5 and N2-6 is coupled to conductor 240a of the set of conductors 240. In some embodiments, conductor 240a of the set of conductors 240 is configured as the write word line WWL, and the gate terminal of each of NFET transistors N2-5 and N2-6 is coupled to the write word line WWL.

A drain terminal of NFET transistor N2-3 is coupled to conductor 230a of the set of conductors 230. In some embodiments, conductor 230a of the set of conductors 230 is configured as the read bit line bar RBLB, and the drain terminal of NFET transistor N2-3 is coupled to the read bit line bar RBLB.

A drain terminal of NFET transistor N2-4 is coupled to conductor 232a of the set of conductors 232. In some embodiments, conductor 232a of the set of conductors 232 is configured as the read bit line RBL, and the drain terminal of NFET transistor N2-4 is coupled to the read bit line RBL.

Read bit lines RBL and read bit line bars RBLB are configured as data output for memory cell 400B. Write bit lines WBL and write bit line bars WBLB are configured as data input for memory cell 400B.

In some embodiments, in a write operation, applying a logical value to a write bit line WBL and the opposite logical value to the write bit line bar WBLB enables writing the logical values on the write bit lines and write bit line bars to memory cell 400B.

In some embodiments, in a read operation, applying a logical value to a read bit line RBL and the opposite logical value to the read bit line bar RBLB enables writing the logical values on the read bit lines and read bit line bars to memory cell 400B.

Each of read bit line RBL/write bit line WBL and read bit line bar RBLB/write bit line bar WBLB is called a data line because the data carried on read bit line RBL/write bit line WBL and read bit line bar RBLB/write bit line bar WBLB are written to and read from corresponding nodes ND and NDB.

In some embodiments, the write driver circuit 202 is configured to perform the write operation of the transposed weight signals Din[M]* to memory cell 400B in the first direction X.

In some embodiments, the read circuit 108 is configured to perform the read operation of the transposed weight signals Din[M]* stored in memory cell 400B in the second direction Y.

In some embodiments, memory cell 400B achieves one or more of the benefits discussed herein.

Other configurations of memory cell 400B are within the scope of the present disclosure.

FIG. 4C is a circuit diagram of a write driver circuit 400C, in accordance with some embodiments.

Write driver circuit 400C is an embodiment of write driver circuit 202 of FIGS. 2, 4A and 5A, and similar detailed description is therefore omitted.

In some embodiments, write driver circuit 400C is configured to operate in a “transpose mode” since the write driver circuit 202 is configured to write the transposed weight signals Din[M]* to the set of memory cell arrays 210 in response to being enabled by the write enable signal WEB.

Write driver circuit 400C includes a PFET P1 and a buffer circuit B1.

An input terminal of buffer circuit B1 is configured to receive the weight signals Din[M]. In some embodiments, the input terminal of buffer circuit B1 is directly coupled to a source of the weight signals Din[M].

An output terminal of buffer circuit B1 is configured to output transposed weight signals Din[M]* in response to being enabled. In some embodiments, buffer circuit B1 is enabled if a first voltage supply node N1 of buffer circuit B1 is electrically coupled to the voltage supply node VDDN.

In some embodiments, the output terminal of buffer circuit B1 is configured to not output transposed weight signals Din[M]* in response to being disabled. In some embodiments, buffer circuit B1 is disabled if the first voltage supply node N1 of buffer circuit B1 is not electrically coupled to the voltage supply node VDDN.

Buffer circuit B1 has a first voltage supply node N1. In some embodiments, the first voltage supply node N1 of buffer circuit B1 is configured to receive a supply voltage VDD by PFET P1. In some embodiments, the second voltage supply node Nd4 of buffer circuit B1 is configured to receive a reference supply voltage VSS by a transistor similar to PFET P1. In some embodiments, the reference supply voltage VSS is different from the supply voltage VDD.

While write driver circuit 400C is described with respect to transposed weight signals Din[M]*, the features of write driver circuit 400C apply in a similar manner to one or more embodiments where transposed weight signals Din[M]* is divided into portions of transposed weight signals, such as at least one of transposed weight signals Din[M1]* or transposed weight signals Din[M2]*, and similar detailed description is therefore omitted.

Other types of circuits, circuit elements or numbers of circuits for buffer circuit B1 are within the scope of the present disclosure. In some embodiments, buffer circuit B1 is replaced with one or more inverters, logic circuits, transistors, registers, multiplexers or latches.

A gate terminal of PFET P1 is configured to receive a write enable signal WEB. A source terminal of PFET P1 is coupled to a voltage supply node VDDN. Voltage supply node VDDN has the supply voltage VDD. A drain terminal of PFET P1 is coupled to the first voltage supply node N1 of buffer circuit B1.

Other types of transistors or numbers of transistors for PFET P1 are within the scope of the present disclosure.

In some embodiments, if PFET P1 is turned off in response to the write enable signal WEB, then the first voltage supply node N1 of buffer circuit B1 is electrically floating, and the buffer circuit B1 is disabled. In some embodiments, if PFET P1 is turned on in response to write enable signal WEB, then the first voltage supply node N1 of buffer circuit B1 is coupled to the supply voltage node VDDN and thus receives supply voltage VDD, and the buffer circuit B1 is enabled.

In some embodiments, due to at least the electrical connection between the write driver circuit 400C and memory cell 400B by at least one of the set of conductors 220, 222, 2224 or 226, the write driver circuit 400C is configured to write the transposed weight signals Din[M]* to the memory cell 400B in response to being enabled by the write enable signal WEB. In some embodiments, the transposed weight signals Din[M]* output by the write driver circuit 400C is the same as the weight signals Din[M] output by the write driver circuit 400C, but at least the electrical connection between the write driver circuit 400C and memory cell 400B causes the transposed weight signals Din[M]* received by the memory cell 400B to be transposed with respect to weight signals Din[M] since the write direction to the memory cell 400B is in the first direction X.

In some embodiments, write driver circuit 400C achieves one or more of the benefits discussed herein.

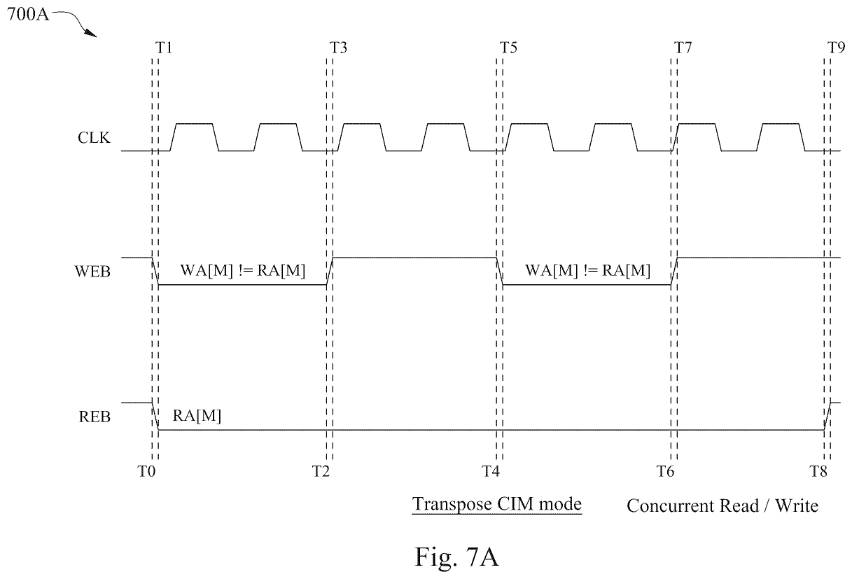

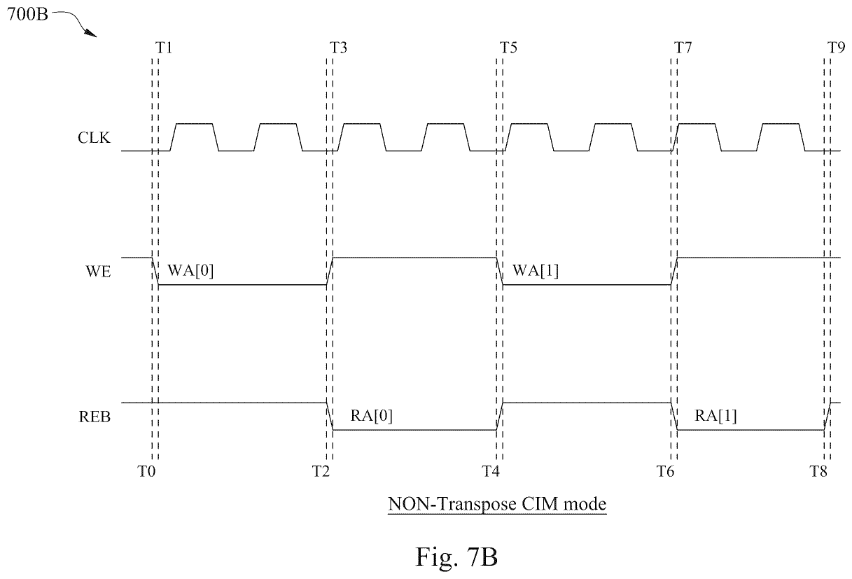

In some embodiments, operations of at least one of memory circuit 400A, memory cell 400B or write driver circuit 400C are further described in at least one of memory circuit 600A of FIG. 6A or waveform 700A of FIG. 7A.

Other configurations or quantities of elements in write driver circuit 400C are within the scope of the present disclosure.

FIG. 5A is a circuit diagram of a memory circuit 500A, in accordance with some embodiments.

Memory circuit 500A is an embodiment of portions of memory device 100 of FIG. 1, and similar detailed description is therefore omitted.

In some embodiments, memory circuit 500A is a non-limiting example of write driver circuit 204 being enabled by the write enable signal WE, and similar detailed description is therefore omitted. In some embodiments, memory circuit 500A is configured to operate in a “non-transpose mode” since the write driver circuit 204 is configured to write the weight signals Din[M] to the set of memory cell arrays 210 in response to being enabled by the write enable signal WE, and the weight signals Din[M] are not transposed.

In some embodiments, memory circuit 500A is memory circuit 200 of FIG. 2, and similar detailed description is therefore omitted.

Memory circuit 500A includes write driver circuit 202, write driver circuit 204, set of memory cell arrays 210, set of MAC circuits 212 and adder circuit 214.

In some embodiments, the write driver circuit 204 is configured to write the weight signals Din[M] to the set of memory cell arrays 210 in response to being enabled by the write enable signal WE.

In some embodiments, the write driver circuit 204 is configured to write the weight signals Din[M1], Din[M2] to corresponding memory cell array 210a, . . . , 210n of the set of memory cell arrays 210 in response to being enabled by the write enable signal WE.

In some embodiments, memory cell array 210a is configured as a single port memory cell in response to the write driver circuit 204 being enabled by the write enable signal WE.

In some embodiments, memory cell array 210n is configured as a single port memory cell in response to the write driver circuit 204 being enabled by the write enable signal WE.

In some embodiments, as shown in FIG. 5A, since the write driver circuit 202 is enabled by the write enable signal WE, then the write driver circuit 202 is electrically coupled to the memory cell array 210a by the set of conductors 230, and the set of conductors 230 (during one or more write operations) is configured as the set of write bit line bars WBLB of memory cell array 210a, and each memory cell array of the memory cell array 210a is configured as a single port memory cell (as shown in FIG. 5B), and the memory cell array 210a is configured to store weight signals Din[M1] during one or more write operations.

In some embodiments, as shown in FIG. 5A, since the write driver circuit 202 is enabled by the write enable signal WE, then the write driver circuit 202 is electrically coupled to the memory cell array 210a by the set of conductors 232, and the set of conductors 232 (during one or more write operations) is configured as the set of write bit lines WBL of memory cell array 210a, each memory cell array of the memory cell array 210a is configured as a single port memory cell (as shown in FIG. 5B), and the memory cell array 210a is configured to store weight signals Din[M1] during one or more write operations.

In some embodiments, as shown in FIG. 5A, since the write driver circuit 202 is enabled by the write enable signal WE, then the write driver circuit 202 is electrically coupled to the memory cell array 210n by the set of conductors 230, and the set of conductors 230 (during one or more write operations) is configured as the set of write bit line bars WBLB of memory cell array 210n, and each memory cell array of the memory cell array 210n is configured as a single port memory cell (as shown in FIG. 5B), and the memory cell array 210n is configured to store weight signals Din[M2] during one or more write operations.

In some embodiments, as shown in FIG. 5A, since the write driver circuit 202 is enabled by the write enable signal WE, then the write driver circuit 202 is electrically coupled to the memory cell array 210n by the set of conductors 232, and the set of conductors 232 (during one or more write operations) is configured as the set of write bit lines WBL of memory cell array 210n, each memory cell array of the memory cell array 210n is configured as a single port memory cell (as shown in FIG. 5B), and the memory cell array 210n is configured to store weight signals Din[M2] during one or more write operations.

In some embodiments, the write driver circuit 204 is configured to perform the write operation of the weight signals Din[M] in the second direction Y. In some embodiments, the write driver circuit 204 is configured to perform the write operation of the weight signals Din[M1] in the second direction Y. In some embodiments, the write driver circuit 204 is configured to perform the write operation of the weight signals Din[M2] in the second direction Y.

In some embodiments, the set of conductors 230 is configured as the set of write bit line bars WBLB of memory cell array 210a during one or more write operations of memory cell 500B. In some embodiments, the set of conductors 232 is configured as the set of write bit lines WBL of memory cell array 210a during one or more write operations of memory cell 500B.

In some embodiments, the set of conductors 230 is configured as the set of write bit line bars WBLB of memory cell array 210n during one or more write operations of memory cell 500B. In some embodiments, the set of conductors 232 is configured as the set of write bit lines WBL of memory cell array 210n during one or more write operations of memory cell 500B.

In some embodiments, the set of conductors 230 is configured as the set of read bit line bars RBLB of memory cell array 210a during one or more read operations of memory cell 500B. In some embodiments, the set of conductors 232 is configured as the set of read bit lines RBL of memory cell array 210a during one or more read operations of memory cell 500B.

In some embodiments, the set of conductors 230 is configured as the set of read bit line bars RBLB of memory cell array 210n during one or more read operations of memory cell 500B. In some embodiments, the set of conductors 232 is configured as the set of read bit lines RBL of memory cell array 210n during one or more read operations of memory cell 500B.

In some embodiments, the set of conductors 244 is configured as the set of read word lines RWL of memory cell array 210a during one or more read operations of memory cell 500B. In some embodiments, the set of conductors 246 is configured as the set of read word lines RWL of memory cell array 210n during one or more read operations of memory cell 500B. In some embodiments, the set of read word lines RWL in FIG. 5A extends in the first direction X.

In some embodiments, the set of conductors 244 is configured as the set of write word lines WWL of memory cell array 210a during one or more write operations of memory cell 500B. In some embodiments, the set of conductors 244 is configured as the set of write word lines WWL of memory cell array 210n during one or more write operations of memory cell 500B. In some embodiments, the set of write word lines WWL in FIG. 5A extends in the first direction X.

In some embodiments, memory circuit 500A achieves one or more of the benefits discussed herein.

Other configurations or quantities of elements in memory circuit 500A are within the scope of the present disclosure.

FIG. 5B is a circuit diagram of a memory cell 500B usable in FIGS. 1, 2, 3 and 5A, in accordance with some embodiments.

Memory cell 500B is usable as one or more memory cells MC in at least one of memory cell array 112 of FIG. 1.

Memory cell 500B is usable as one or more memory cells MC in at least one memory cell array in the set of memory cell arrays 210 of FIG. 5A, and similar detailed description is therefore omitted.

Memory cell 500B is usable as one or more memory cells MC in at least one memory cell in memory cell arrays 302 of FIG. 3, and similar detailed description is therefore omitted.

Memory cell 500B is similar to memory cell 400B of FIG. 4B, and similar detailed description is therefore omitted. In comparison with memory cell 400B of FIG. 4B, while memory cell 500B includes transistor elements with connections as a dual-port memory cell, memory cell 500B is configured to function as a single port memory cell due to at least the electrical connections of the read bit line RBL, the read bit line bar RBLB, the write bit line WBL and the write bit line bar WBLB.

Memory cell 500B comprises PFET transistors P2-1 and P2-2, and NFET transistors N2-1, N2-2, N2-3, N2-4, N2-5 and N2-6.

In FIG. 5B, a source/drain terminal of NFET transistor N2-3 is coupled to conductor 230a of the set of conductors 230. In some embodiments, conductor 230a of the set of conductors 230 in FIG. 5B is configured as the write bit line bar WBLB, and the source/drain terminal of NFET transistor N2-3 is coupled to the write bit line bar WBLB during one or more write operations of memory cell 500B.

In FIG. 5B, a source/drain terminal of NFET transistor N2-3 is coupled to conductor 230a of the set of conductors 230. In some embodiments, conductor 230a of the set of conductors 230 in FIG. 5B is configured as the read bit line bar RBLB, and the source/drain terminal of NFET transistor N2-3 is coupled to the read bit line bar RBLB during one or more read operations of memory cell 500B.

In FIG. 5B, a source/drain terminal of NFET transistor N2-4 is coupled to conductor 232a of the set of conductors 232. In some embodiments, conductor 232a of the set of conductors 232 in FIG. 5B is configured as the write bit line WBL, and the source/drain terminal of NFET transistor N2-4 is coupled to the write bit line WBL during one or more write operations of memory cell 500B.

In FIG. 5B, a source/drain terminal of NFET transistor N2-4 is coupled to conductor 232a of the set of conductors 232. In some embodiments, conductor 232a of the set of conductors 232 in FIG. 5B is configured as the read bit line RBL, and the source/drain terminal of NFET transistor N2-4 is coupled to the read bit line RBL during one or more read operations of memory cell 500B.

In FIG. 5B, a source/drain terminal of NFET transistor N2-5 is coupled to conductor 220a of the set of conductors 222. In some embodiments, conductor 220a of the set of conductors 220 in FIG. 5B is configured to be electrically floating, thereby causing memory cell 500B to be configured to function as a single port memory cell.

In FIG. 5B, a source/drain terminal of NFET transistor N2-6 is coupled to conductor 222a of the set of conductors 222. In some embodiments, conductor 222a of the set of conductors 222 in FIG. 5B is configured to be electrically floating, thereby causing memory cell 500B to be configured to function as a single port memory cell.

A gate terminal of each of NFET transistors N2-3 and N2-4 is coupled to conductor 244a of the set of conductors 244. In some embodiments, during a read operation of memory cell 500B, conductor 244a of the set of conductors 244 is configured as the read word line RWL, and the gate terminal of each of NFET transistors N2-3 and N2-4 is coupled to the read word line RWL.

In some embodiments, during a write operation of memory cell 500B, conductor 244a of the set of conductors 244 is configured as the write word line WWL, and the gate terminal of each of NFET transistors N2-3 and N2-4 is coupled to the write word line WWL.

A gate terminal of each of NFET transistors N2-5 and N2-6 is coupled to conductor 240a of the set of conductors 240. In some embodiments, a voltage of conductor 240a of the set of conductors 240 in FIG. 5B is configured to have a value equal to a logically high (e.g., logic 1) thereby causing each of NFET transistors N2-5 and N2-6 to turn off, thereby causing memory cell 500B to be configured to function as a single port memory cell. In some embodiments, conductor 240a of the set of conductors 240 in FIG. 5B is configured to be electrically floating, thereby causing memory cell 500B to be configured to function as a single port memory cell.

Read bit lines RBL and read bit line bars RBLB are configured as data output for memory cell 500B. Write bit lines WBL and write bit line bars WBLB are configured as data input for memory cell 500B.

In some embodiments, since memory cell 500B is configured to function as a single port memory cell, then a read operation of memory cell 500B does not overlap in time with a write operation of memory cell 500B (as shown in FIG. 7B). Stated differently, since memory cell 500B is configured to function as a single port memory cell, then read and write operations for memory cell 500B occur during different windows of time, in accordance with some embodiments.

In some embodiments, the write driver circuit 204 is configured to perform the write operation of the weight signals Din[M] to memory cell 500B in the second direction Y.

In some embodiments, the read circuit 108 is configured to perform the read operation of the weight signals Din[M] stored in memory cell 500B in the second direction Y.

Other configurations of memory cell 500B are within the scope of the present disclosure.

FIG. 5C is a circuit diagram of a write driver circuit 500C, in accordance with some embodiments.

Write driver circuit 500C is an embodiment of write driver circuit 204 of FIGS. 2, 4A and 5A, and similar detailed description is therefore omitted.

In some embodiments, write driver circuit 500C is configured to operate in a “non-transpose mode” since the write driver circuit 204 is configured to write the weight signals Din[M] to the set of memory cell arrays 210 in response to being enabled by the write enable signal WE.

Write driver circuit 500C includes a PFET P2 and a buffer circuit B2.

In some embodiments, buffer circuit B2 is similar to buffer circuit B1 of FIG. 4C, and PFET P2 is similar to PFET P1 of FIG. 4C, and similar detailed description is therefore omitted.

An input terminal of buffer circuit B2 is configured to receive the weight signals Din[M]. In some embodiments, the input terminal of buffer circuit B2 is directly coupled to a source of the weight signals Din[M].

An output terminal of buffer circuit B2 is configured to output weight signals Din[M] in response to being enabled. In some embodiments, buffer circuit B2 is enabled if a first voltage supply node N2 of buffer circuit B2 is electrically coupled to the voltage supply node VDDN.

In some embodiments, the output terminal of buffer circuit B2 is configured to not output weight signals Din[M] in response to being disabled. In some embodiments, buffer circuit B2 is disabled if the first voltage supply node N2 of buffer circuit B2 is not electrically coupled to the voltage supply node VDDN.

Buffer circuit B2 has a first voltage supply node N2. In some embodiments, the first voltage supply node N2 of buffer circuit B2 is configured to receive a supply voltage VDD by PFET P2. In some embodiments, the second voltage supply node Nd4 of buffer circuit B2 is configured to receive the reference supply voltage VSS by a transistor similar to PFET P2.

While write driver circuit 500C is described with respect to weight signals Din[M], the features of write driver circuit 500C apply in a similar manner to one or more embodiments where weight signals Din[M] is divided into portions of weight signals, such as at least one of weight signals Din[M1] or weight signals Din[M2], and similar detailed description is therefore omitted.

Other types of circuits, circuit elements or numbers of circuits for buffer circuit B2 are within the scope of the present disclosure. In some embodiments, buffer circuit B2 is replaced with one or more inverters, logic circuits, transistors, registers, multiplexers or latches.

A gate terminal of PFET P2 is configured to receive a write enable signal WE. A source terminal of PFET P2 is coupled to a voltage supply node VDDN. Voltage supply node VDDN has the supply voltage VDD. A drain terminal of PFET P2 is coupled to the first voltage supply node N2 of buffer circuit B2.

Other types of transistors or numbers of transistors for PFET P2 are within the scope of the present disclosure.

In some embodiments, if PFET P2 is turned off in response to the write enable signal WE, then the first voltage supply node N2 of buffer circuit B2 is electrically floating, and the buffer circuit B2 is disabled. In some embodiments, if PFET P2 is turned on in response to write enable signal WE, then the first voltage supply node N2 of buffer circuit B2 is coupled to the supply voltage node VDDN and thus receives supply voltage VDD, and the buffer circuit B2 is enabled.

In some embodiments, due to at least the electrical connection between the write driver circuit 500C and memory cell 500B by at least one of the set of conductors 230, 232, 244 or 246, the write driver circuit 500C is configured to write the weight signals Din[M] to the memory cell 500B in response to being enabled by the write enable signal WE. In some embodiments, the weight signals Din[M] output by the write driver circuit 500C is the same as the weight signals Din[M] output by the write driver circuit 500C, and at least the electrical connection between the write driver circuit 500C and memory cell 500B causes the weight signals Din[M] received by the memory cell 500B to not be transposed with respect to the weight signals Din[M] received by write driver circuit 400C since the write direction to the memory cell 500B is in the second direction Y.

In some embodiments, write driver circuit 500C achieves one or more of the benefits discussed herein.

In some embodiments, operations of at least one of memory circuit 500A, memory cell 500B or write driver circuit 500C are further described in at least one of memory circuit 600B of FIG. 6B or waveform 700B of FIG. 7B.

Other configurations or quantities of elements in write driver circuit 500C are within the scope of the present disclosure.

FIG. 6A is a diagram 600A of performing a write/read operation in a transpose mode of memory circuit 400A, in accordance with some embodiments.

In some embodiments, FIG. 6A is a non-limiting example of a write/read operation performed by memory circuit 400A of FIG. 4A, and similar detailed description is therefore omitted. In some embodiments, the write/read operation performed by memory circuit 600A is shown in the graph of waveforms 700A of FIG. 7A, and similar detailed description is therefore omitted.

Diagram 600A includes an input matrix 602, transposed weight signals 604, an input signal 606, and a MAC output data 620. In some embodiments, at least one of input matrix 602, transposed weight signals 604, set of input data 606 or MAC output data 620 is a corresponding matrix.

In some embodiments, the input matrix 602 corresponds to the weight signals Din[M] of FIG. 4A, the transposed weight signals 604 corresponds to the transposed weight signals Din[M]* of FIG. 4A, the set of input data corresponds to values of the set of input data Xin of FIG. 4A, the MAC output data 620 corresponds to values of the set of data OU of FIG. 4A, a MAC circuit 612a corresponds to one or more MAC circuits of the set of MAC circuits 212 of FIG. 4A, and similar detailed description is therefore omitted.

The input matrix 602 includes rows and columns of weight signals. The weight signals include A, B, . . . , P.

The transposed weight signals 604 include rows and columns of transposed weight signals. The transposed weight signals include A, B, . . . , P. The transposed weight signals 604 are transposed with respect to the input matrix 602. In some embodiments, the transposed weight signals 604 are generated by write input driver 202, and similar detailed description is therefore omitted.

In some embodiments, the write operation of FIG. 6A is performed in the first direction X. In some embodiments, the read operation of FIG. 6A is performed in the second direction Y.

The set of input data 606 includes rows and columns of values for the set of input data. The set of input data include data 1, 2, . . . , 16.

Input data XIN1 has values in column 1 of the set of input data 606. Input data XIN2 has values in column 2 of the set of input data 606. Input data XIN3 has values in column 3 of the set of input data 606. Input data XIN4 has values in column 4 of the set of input data 606.

In some embodiments, a MAC circuit 612a is configured to perform a MAC operation on a column of data from transposed weight signals 604 and a row of input data from the set of input data 606. For example, in some embodiments, the column of data 604a is read from the transposed weight signals 604, and MAC circuit 612a is configured to perform a MAC operation on the column of data 604a and the row of input data 606a, thereby generating the output MAC data 620.

Diagram 600A achieves one or more of the benefits discussed herein.

Other sizes for at least one of input matrix 602, transposed weight signals 604, input signal 606 or MAC output data 620 is within the scope of the present disclosure.

FIG. 6B is a diagram 600B of performing a write/read operation in a non-transpose mode of memory circuit 400A, in accordance with some embodiments.

In some embodiments, FIG. 6B is a non-limiting example of a write/read operation performed by memory circuit 400B of FIG. 4B, and similar detailed description is therefore omitted. In some embodiments, the write/read operation performed by memory circuit 600B is shown in the graph of waveforms 700B of FIG. 7B, and similar detailed description is therefore omitted.

In some embodiments, diagram 600B is a variation of diagram 600A of FIG. 6A, and similar detailed description is therefore omitted. In comparison with diagram 600A of FIG. 6A, weight signals 614 replace transposed weight signals 604 of FIG. 6A, MAC output data 630 replaces MAC output data 620 of FIG. 6A, and a MAC circuit 612a replaces MAC circuit 612a of FIG. 6A, and similar detailed description is therefore omitted.

Diagram 600B includes the input matrix 602, weight signals 614, the input signal 606, and a MAC output data 630. In some embodiments, at least one of input matrix 602, weight signals 614, set of input data 606 or MAC output data 630 is a corresponding matrix.

In some embodiments, the input matrix 602 corresponds to the weight signals Din[M] of FIG. 5A, the weight signals 614 corresponds to the weight signals Din[M] of FIG. 5A output by the write driver circuit 204, the set of input data 606 corresponds to values of the set of input data Xin of FIG. 5A, the MAC output data 630 corresponds to values of the set of data OU of FIG. 5A, a MAC circuit 612a corresponds to one or more MAC circuits of the set of MAC circuits 212 of FIG. 5A, and similar detailed description is therefore omitted.

The weight signals 614 include rows and columns of weight signals. The weight signals include A, B, . . . , P. The weight signals 614 are not transposed with respect to the input matrix 602. In some embodiments, the weight signals 614 are generated by write input driver 204, and similar detailed description is therefore omitted.

In some embodiments, the write operation of FIG. 6B is performed in the second direction Y. In some embodiments, the read operation of FIG. 6B is performed in the second direction Y.

In some embodiments, a MAC circuit 612b is configured to perform a MAC operation on a column of data from weight signals 614 and a row of input data from the set of input data 606. For example, in some embodiments, the column of data 614a is read from the weight signals 614, and MAC circuit 612b is configured to perform a MAC operation on the column of data 614a and the row of input data 606a, thereby generating the output MAC data 630.

Diagram 600B achieves one or more of the benefits discussed herein.

Other sizes for at least one of input matrix 602, weight signals 614, input signal 606 or MAC output data 630 is within the scope of the present disclosure.

FIGS. 7A-7B are corresponding graphs of corresponding waveforms 700A-700B, in accordance with some embodiments.

In some embodiments, waveform 700A is an example of one or more write and read operations of the memory circuit 400A of FIG. 4A, and similar detailed description is therefore omitted.

In some embodiments, waveform 700B is an example of one or more write and read operations of the memory circuit 500A of FIG. 5A, and similar detailed description is therefore omitted.

In some embodiments, a clock signal is a memory clock used by memory circuit 500A of FIG. 5A.

In some embodiments, from time T1-T2 of FIG. 7A, a concurrent read and write operation of a first memory cell similar to memory cell 400B are performed by memory circuit 400A, and from time T5-T6 of FIG. 7A, another concurrent read and write operation of a second memory cell similar to memory cell 400B are performed by memory circuit 400A.

In some embodiments, for brevity waveform 700A is described as a concurrent read and write operation of a first memory cell and a second memory cell, but FIG. 7A is applicable to a concurrent read and write operation of other numbers of memory cells.

In some embodiments, by utilizing memory circuit 400A of FIG. 4A, the memory cell array 210 configured with a bi-directional dual-Port cell achieves better write throughput and MAC throughput than other approaches.

At time T0, the read enable signal REB transitions from logic 1 to logic 0, and the write enable signal WEB transitions from logic 1 to logic 0. In some embodiments, when the read enable signal REB is logic 1, then the read circuit 108 is disabled. In some embodiments, when the write enable signal WEB is logic 1, then the write driver circuit 202 is disabled.

In some embodiments, from time T1-T8 of FIG. 7A, the read enable signal REB is equal to logic 0, thereby enabling the read circuit 108. In some embodiments, by enabling the read circuit 108, the read circuit 108 is able to perform one or more read operations of the first memory cell similar to memory cell 400B, and one or more read operations of the second memory cell similar to memory cell 400B.

In some embodiments, from time T1-T2 of FIG. 7A, the write enable signal WEB is equal to logic 0, thereby enabling the write driver circuit 202. In some embodiments, by enabling the write driver circuit 202, the write driver circuit 202 is able to perform one or more write operations of the first memory cell similar to memory cell 400B.

In some embodiments, from time T1-T2 of FIG. 7A, a concurrent read and write operation of the first memory cell similar to memory cell 400B are performed by memory circuit 400A.

At time T2, the write enable signal WEB transitions from logic 0 to logic 1.

At time T3, the write enable signal WEB is a logic 1.

At time T4, the write enable signal WEB transitions from logic 1 to logic 0.

At time T5, the write enable signal WEB is a logic 0.

In some embodiments, from time T5-T6 of FIG. 7A, the write enable signal WEB is equal to logic 0, thereby enabling the write driver circuit 202. In some embodiments, by enabling the write driver circuit 202, the write driver circuit 202 is able to perform one or more write operations of the first memory cell similar to memory cell 400B.

In some embodiments, from time T5-T6 of FIG. 7A, a concurrent read and write operation of the second memory cell similar to memory cell 400B are performed by memory circuit 400A.

At time T6, the write enable signal WEB transitions from logic 0 to logic 1.

At time T7, the write enable signal WEB is logic 1.

At time T8, the read enable signal REB transitions from logic 0 to logic 1.

At time T9, the read enable signal REB is a logic 1.

Other configurations of waveform 700A are within the scope of the present disclosure.

FIG. 7B is a corresponding graph of corresponding waveform 700B, in accordance with some embodiments.

In some embodiments, from time T1-T2 of FIG. 7B, a write operation of a first memory cell similar to memory cell 500B is performed by memory circuit 500A, and a read operation of the first memory cell similar to memory cell 500B is performed by read circuit 108.

In some embodiments, from time T5-T6 of FIG. 7B, another write operation of a second memory cell similar to memory cell 500B is performed by memory circuit 500A, and another read operation of the second memory cell similar to memory cell 500B is performed by read circuit 108.

In some embodiments, for brevity waveform 700B is described as non-overlapping read and write operations of a first memory cell and a second memory cell, but FIG. 7B is applicable to non-overlapping read and write operations of other numbers of memory cells.

In some embodiments, by utilizing memory circuit 500A of FIG. 5A, the memory cell array 210 configured with a single direction, single port memory cell.

At time T0, the write enable signal WE transitions from logic 1 to logic 0. In some embodiments, when the write enable signal WE is logic 1, then the write driver circuit 204 is disabled.

At time T1, the write enable signal WE is logic 0. In some embodiments, from time T1-T2 of FIG. 7B, the write enable signal WE is equal to logic 0, thereby enabling the write driver circuit 204. In some embodiments, by enabling the write driver circuit 204, the write driver circuit 204 is able to perform one or more write operations of the first memory cell similar to memory cell 500B.

At time T2, the read enable signal REB transitions from logic 1 to logic 0, and the write enable signal WE transitions from logic 0 to logic 1.

At time T3, the read enable signal REB is logic 0.

In some embodiments, from time T3-T4 of FIG. 7B, the read enable signal REB is equal to logic 0, thereby enabling the read circuit 108. In some embodiments, by enabling the read circuit 108, the read circuit 108 is able to perform one or more read operations of the first memory cell similar to memory cell 500B.

At time T4, the write enable signal WE transitions from logic 1 to logic 0, and the read enable signal REB transitions from logic 0 to logic 1.

At time T5, the write enable signal WE is a logic 0, and the read enable signal REB is logic 1.

In some embodiments, from time T5-T6 of FIG. 7B, the write enable signal WE is equal to logic 0, thereby enabling the write driver circuit 204. In some embodiments, by enabling the write driver circuit 204, the write driver circuit 204 is able to perform one or more write operations of the second memory cell similar to memory cell 500B.

At time T6, the write enable signal WE transitions from logic 0 to logic 1, and the read enable signal REB transitions from logic 1 to logic 0.

At time T7, the write enable signal WE is a logic 1, and the read enable signal REB is logic 0.

In some embodiments, from time T7-T8 of FIG. 7B, the read enable signal REB is equal to logic 0, thereby enabling the read circuit 108. In some embodiments, by enabling the read circuit 108, the read circuit 108 is able to perform one or more read operations of the second memory cell similar to memory cell 500B.

At time T8, the read enable signal REB transitions from logic 0 to logic 1.

At time T9, the read enable signal REB is a logic 1.

In some embodiments, by using waveforms 700A or 700B the corresponding write driver circuit 400A or 500A achieves one or more benefits discussed herein in the present application.

Other configurations of waveforms 700B are within the scope of the present disclosure.

FIG. 8A is a schematic diagram of a memory device 800A, in accordance with some embodiments.

The memory device 800A comprises memory macros 802, 804, 806, 808 and memory controller 820. In some embodiments, one or more of the memory macros 802, 804, 806, 808 correspond to memory macro 810, and/or memory controller 820 corresponds to the memory controller 120. In some embodiments, one or more of the memory macros 802, 804, 806, 808 correspond to memory circuit 102, and/or memory controller 820 corresponds to the memory controller 120.

In the example configuration in FIG. 8A, the memory controller 820 is a common memory controller for the memory macros 802, 804, 806, 808. In at least one embodiment, at least one of the memory macros 802, 804, 806, 808 has its own memory controller. The number of four memory macros in the memory device 800A is an example. Other configurations are within the scopes of various embodiments.

The memory macros 802, 804, 806, 808 are coupled to each other in sequence, with output data of a preceding memory macro being input data for a subsequent memory macro. For example, input data DIN are input into the memory macro 802. In some embodiments, input data DIN is received data IN of FIG. 1, and similar detailed description is therefore omitted. The memory macro 802 performs one or more CIM operations based on the input data DIN and one of the weight data W or transposed weight data W* (shown in FIG. 1) stored in the memory macro 802, and generates output data DOUT2 as results of the CIM operations. The output data DOUT2 are supplied as input data DIN4 of the memory macro 804. The memory macro 804 performs one or more CIM operations based on the input data DIN4 and one of the weight data W or transposed weight data W* stored in the memory macro 804, and generates output data DOUT4 as results of the CIM operations. The output data DOUT4 are supplied as input data DIN6 of the memory macro 806. The memory macro 806 performs one or more CIM operations based on the input data DIN6 and one of the weight data W or transposed weight data W* stored in the memory macro 806, and generates output data DOUT6 as results of the CIM operations. The output data DOUT6 are supplied as input data DIN8 of the memory macro 808. The memory macro 808 performs one or more CIM operations based on the input data DIN8 and one of the weight data W or transposed weight data W* stored in the memory macro 808, and generates output data DOUT as results of the CIM operations.

In some embodiments, one or more of the input data DIN, DIN4, DIN6, DIN8 correspond to the received data IN described with respect to FIG. 1, and/or one or more of the output data DOUT2, DOUT4, DOUT6, DOUT correspond to the output data D_OUT described with respect to FIG. 1, and similar detailed description is therefore omitted. In at least one embodiment, the described configuration of the memory macros 802, 804, 806, 808 implements a neural network. In at least one embodiment, one or more advantages described herein are achievable by the memory device 800A.

Other configurations or quantities of elements in memory device 800A are within the scope of the present disclosure.

FIG. 8B is a schematic diagram of a neural network 800B, in accordance with some embodiments.

The neural network 800B comprises a plurality of layers A-E each comprising a plurality of nodes (or neurons). The nodes in successive layers of the neural network 800B are connected with each other by a matrix or array of connections. For example, the nodes in layers A and B are connected with each other by connections in a matrix 812, the nodes in layers B and C are connected with each other by connections in a matrix 814, the nodes in layers C and D are connected with each other by connections in a matrix 816, and the nodes in layers D and E are connected with each other by connections in a matrix 818. Layer A is an input layer configured to receive input data 811. The input data 811 propagate through the neural network 800B, from one layer to the next layer via the corresponding matrix of connections between the layers. As the data propagate through the neural network 800B, the data undergo one or more computations, and are output as output data 819 from layer E which is an output layer of the neural network 800B. Layers B, C, D between input layer A and output layer E are sometimes referred to as hidden or intermediate layers. The number of layers, number of matrices of connections, and number of nodes in each layer in FIG. 8B are examples. Other configurations are within the scopes of various embodiments. For example, in at least one embodiment, the neural network 800B includes no hidden layer, and has an input layer connected by one matrix of connections to an output layer. In one or more embodiments, the neural network 800B has one, two, or more than three hidden layers.

In some embodiments, the matrices 812, 814, 816, 818 are correspondingly implemented by the memory macros 802, 804, 806, 808, the input data 811 corresponds to the input data DIN, and the output data 819 corresponds to the output data DOUT, and similar detailed description is therefore omitted. Specifically, in the matrix 812, a connection between a node in layer A and another node in layer B has a corresponding weight. For example, a connection between node A1 and node B1 has a weight W(A1,B1) which corresponds to a weight value or transposed weight value stored in the memory cell array of the memory macro 802. The memory macros 804, 806, 808 are configured in a similar manner. The weight data W or transposed weight data W* in one or more of the memory macros 802, 804, 806, 808 are updated, e.g., by a processor and through the memory controller 820, as machine learning is performed using the neural network 800B. One or more advantages described herein are achievable in the neural network 800B implemented in whole or in part by one or more memory macros and/or memory devices in accordance with some embodiments.

Other configurations or quantities of elements in neural network 800B are within the scope of the present disclosure.

FIG. 8C is a schematic diagram of an integrated circuit (IC) device 800C, in accordance with some embodiments.

The IC device 800C is an embodiment of memory device 100 of FIG. 1 or memory device 800A of FIG. 8A, and similar detailed description is therefore omitted.

The IC device 800C comprises one or more hardware processors 832, one or more memory devices 834 coupled to the processors 832 by one or more buses 836. In some embodiments, the one or more hardware processors 832 is useable as one or more components in controller 120 of FIG. 1 or memory controller 820 in FIG. 8A, and similar detailed description is therefore omitted. In some embodiments, the one or more memory devices 834 is useable as one or more components in memory circuit 102 of FIG. 1, memory macro 810 of FIG. 1 or one or more of memory macros 802, 804, 806 or 808 in FIG. 8A, and similar detailed description is therefore omitted.

In some embodiments, the IC device 800C comprises one or more further circuits including, but not limited to, cellular transceiver, global positioning system (GPS) receiver, network interface circuitry for one or more of Wi-Fi, USB, Bluetooth, or the like. Examples of the processors 832 include, but are not limited to, a central processing unit (CPU), a multi-core CPU, a neural processing unit (NPU), a graphics processing unit (GPU), a digital signal processor (DSP), a field-programmable gate array (FPGA), an application-specific integrated circuit (ASIC), other programmable logic devices, a multimedia processor, an image signal processors (ISP), or the like. Examples of the memory devices 834 include one or more memory devices and/or memory macros described herein. In at least one embodiment, each of the processors 832 is coupled to a corresponding memory device among the memory devices 834.

Because the one or more of the memory devices 834 are CIM memory devices, various computations are performed in the memory devices which reduces the computing workload of the corresponding processor, reduces memory access time, and improves performance. In at least one embodiment, the IC device 800C is a system-on-a-chip (SOC). In at least one embodiment, one or more advantages described herein are achievable by the IC device 800C.

Other configurations or quantities of elements in IC device 800C are within the scope of the present disclosure.

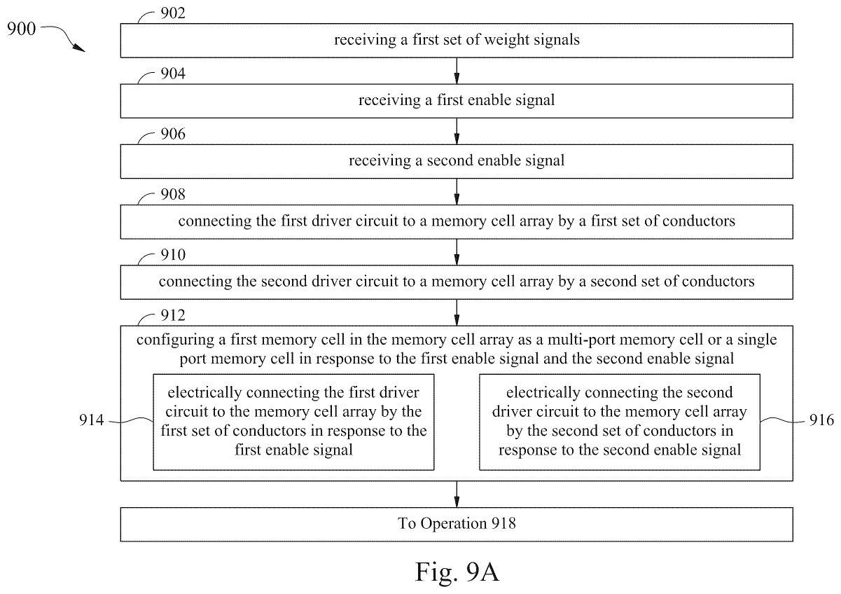

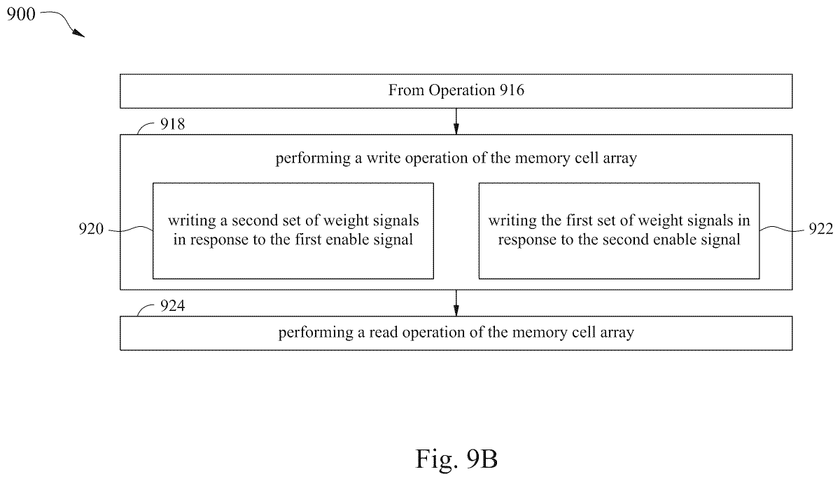

FIGS. 9A-9B are a flowchart of a method 900 of operating a circuit, in accordance with some embodiments.

In some embodiments, FIGS. 9A-9B are a flowchart of method 900 of operating a memory circuit, such as memory device 100 of FIG. 1, memory circuit 200 of FIG. 2, memory cell array 300 of FIG. 3, memory circuit 400A of FIG. 4A, memory cell 400B of FIG. 4B, write driver circuit 400C of FIG. 4C, memory circuit 500A of FIG. 5A, memory cell 500B of FIG. 5B, write driver circuit 500C of FIG. 5C, diagram 600A of FIG. 6A, diagram 600B of FIG. 6B, waveform 700A of FIG. 7A, waveform 700B of FIG. 7B, memory device 800A of FIG. 8A, neural network 800B of FIG. 8B or IC device 800C of FIG. 8C.

In some embodiments, method 900 uses one or more aspects of waveforms 700A-700B of corresponding FIGS. 7A-7B.

It is understood that additional operations may be performed before, during, and/or after the method 900 depicted in FIGS. 9A-9B, and that some other processes may only be briefly described herein. In some embodiments, other order of operations of method 900 is within the scope of the present disclosure. Method 900 include exemplary operations, but the operations are not necessarily performed in the order shown. Operations may be added, replaced, changed order, and/or eliminated as appropriate, in accordance with the spirit and scope of disclosed embodiments. In some embodiments, one or more of the operations of method 900 is not performed.

In operation 902 of method 900, a first set of weight signals is received by a first driver circuit and a second driver circuit.

In some embodiments, the first driver circuit of method 900 includes at least one of write driver circuit 202. In some embodiments, the second driver circuit of method 900 includes at least one of write driver circuit 204.

In some embodiments, the first set of weight signals of method 900 includes at least the weight signals Din[M].

In operation 904 of method 900, a first enable signal is received by the first driver circuit. In some embodiments, the first driver circuit is configured to be enabled or disabled in response to the first enable signal.

In some embodiments, the first enable signal of method 900 includes at least the write enable signal WEB.

In operation 906 of method 900, a second enable signal is received by the second driver circuit. In some embodiments, the second driver circuit is configured to be enabled or disabled in response to the second enable signal.

In some embodiments, the second enable signal of method 900 includes at least the write enable signal WE. In some embodiments, the second enable signal is inverted from the first enable signal.

In operation 908 of method 900, the first driver circuit is connected to a memory cell array by a first set of conductors.

In some embodiments, the memory cell array of method 900 includes at least the memory cell array 112 or 210.

In some embodiments, the first set of conductors of method 900 includes at least the set of conductors 220, 222, 224 or 226.

In operation 910 of method 900, the second driver circuit is connected to the memory cell array by a second set of conductors.

In some embodiments, the second set of conductors of method 900 includes at least the set of conductors 230 or 232.

In operation 912 of method 900, a first memory cell in the memory cell array is configured as a multi-port memory cell or a single port memory cell in response to the first enable signal and the second enable signal.

In some embodiments, the first memory cell in the memory cell array of method 900 includes at least one or more of memory cells MC, 400B or 500B.

In some embodiments, operation 912 includes either operation 914 or 916.

In operation 914 of method 900, the first driver circuit is electrically connected to the memory cell array by the first set of conductors in response to the first enable signal.

In operation 916 of method 900, the second driver circuit is electrically connected to the memory cell array by the second set of conductors in response to the second enable signal.

In operation 918 of method 900, a write operation of the memory cell array is performed.

In some embodiments, operation 918 includes operation 920 or 922.

In operation 920 of method 900, a second set of weight signals is written by the first driver circuit in response to the first enable signal. In some embodiments, the second set of weight signals is transposed with respect to the first set of weight signals.

In some embodiments, the second set of weight signals of method 900 includes at least the transposed weight signals Din[M]*. In some embodiments, the second set of weight signals of method 900 includes at least the transposed weight signals Din[M1]* or Din[M2]*.

In operation 922 of method 900, the first set of weight signals is written by the second driver circuit in response to the second enable signal.

In some embodiments, the first set of weight signals of operation 922 includes at least the weight signals Din[M]. In some embodiments, the first set of weight signals of operation 922 includes at least the weight signals Din[M1] or Din[M2].

In operation 924 of method 900, a read operation is performed by a read circuit in response to the read circuit being enabled by a third enable signal.

In some embodiments, the third enable signal of method 900 includes at least the read enable signal REB.

By using method 900, the memory circuit operates to achieve one or more benefits discussed herein in the present disclosure.

While method 900 was described above with reference to a single memory cell in memory cell array 112 or 210, it is understood that method 900 applies to each memory cell in memory cell array 112 or 210, in some embodiments.

Other operations of method 900 are within the scope of the present disclosure.

Furthermore, the low or high logical value of various signals used in the above description is also for illustration. Embodiments of the disclosure are not limited to a particular logical value when a signal is activated and/or deactivated. Selecting different logical values is within the scope of various embodiments. Selecting different numbers of elements in FIGS. 1-11C is within the scope of various embodiments.

It will be readily seen by one of ordinary skill in the art that one or more of the disclosed embodiments fulfill one or more of the advantages set forth above. After reading the foregoing specification, one of ordinary skill will be able to affect various changes, substitutions of equivalents and various other embodiments as broadly disclosed herein. It is therefore intended that the protection granted hereon be limited only by the definition contained in the appended claims and equivalents thereof.

One aspect of this description relates to a memory circuit. In some embodiments, the memory circuit includes a memory cell array configured to store a first set of weight signals or a second set of weight signals, the second set of weight signals being transposed with respect to the first set of weight signals. In some embodiments, the memory circuit includes a multiply-accumulate (MAC) circuit coupled to the memory cell array, and configured to generate a first set of data in response to a set of input data and one of the first set of weight signals or the second set of weight signals. In some embodiments, the memory circuit includes a first driver circuit coupled to the memory cell array, and configured to write the second set of weight signals to the memory cell array in response to being enabled by a first enable signal. In some embodiments, the memory circuit includes a second driver circuit coupled to the MAC circuit and the memory cell array, and configured to write the first set of weight signals to the memory cell array in response to being enabled by a second enable signal, the second enable signal being inverted from the first enable signal.

Another aspect of this description relates to a memory circuit. In some embodiments, the memory circuit includes a first memory cell array configured to store a first set of weight signals or a second set of weight signals, the second set of weight signals being transposed with respect to the first set of weight signals. In some embodiments, the memory circuit further includes a first multiply-accumulate (MAC) circuit coupled to the first memory cell array, and configured to generate a first set of data in response to a first set of input data and one of the first set of weight signals or the second set of weight signals. In some embodiments, the memory circuit further includes a first driver circuit coupled to the first memory cell array, and configured to write the second set of weight signals to the first memory cell array in response to being enabled by a first enable signal, the first driver circuit being configured to be enabled or disabled in response to the first enable signal. In some embodiments, the memory circuit further includes a second driver circuit coupled to the first memory cell array, and configured to write the first set of weight signals to the first memory cell array in response to being enabled by a second enable signal, the second enable signal being inverted from the first enable signal, the second driver circuit being configured to be enabled or disabled in response to the second enable signal. In some embodiments, the memory circuit further includes a read circuit coupled to the first memory cell array and the first MAC circuit, and configured to read the first memory cell array in response to being enabled by a third enable signal.

Still another aspect of this description relates to a method of operating a memory circuit. In some embodiments, the method includes receiving, by a first driver circuit and a second driver circuit, a first set of weight signals. In some embodiments, the method further includes receiving, by the first driver circuit, a first enable signal, the first driver circuit being configured to be enabled or disabled in response to the first enable signal. In some embodiments, the method further includes receiving, by the second driver circuit, a second enable signal, the second driver circuit being configured to be enabled or disabled in response to the second enable signal, the second enable signal being inverted from the first enable signal. In some embodiments, the method further includes configuring a first memory cell in a memory cell array as a multi-port memory cell or a single port memory cell in response to the first enable signal and the second enable signal. In some embodiments, the method further includes performing a write operation of the memory cell array. In some embodiments, the performing the write operation of the memory cell array includes writing, by the first driver circuit, a second set of weight signals in response to the first enable signal, or writing, by the second driver circuit, the first set of weight signals in response to the second enable signal. In some embodiments, the second set of weight signals being transposed with respect to the first set of weight signals. In some embodiments, the method further includes performing, by a read circuit, a read operation of the memory cell array in response to being enabled by a third enable signal.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory circuit, comprising:
a memory cell array configured to store a first set of weight signals or a second set of weight signals, the second set of weight signals being transposed with respect to the first set of weight signals;
a multiply-accumulate (MAC) circuit coupled to the memory cell array, and configured to generate a first set of data in response to a set of input data and one of the first set of weight signals or the second set of weight signals;
a first driver circuit coupled to the memory cell array, and configured to write the second set of weight signals to the memory cell array in response to being enabled by a first enable signal; and
a second driver circuit coupled to the memory cell array, and configured to write the first set of weight signals to the memory cell array in response to being enabled by a second enable signal, the second enable signal being inverted from the first enable signal.

2. The memory circuit of claim 1, wherein
the first driver circuit is configured to be enabled or disabled in response to the first enable signal; and
the second driver circuit is configured to be enabled or disabled in response to the second enable signal.

3. The memory circuit of claim 2, further comprising:
an adder circuit coupled to the MAC circuit, and configured to generate a first set of output signals in response to the first set of data.

4. The memory circuit of claim 1, wherein the memory cell array comprises:
an array of dual-port memory cells, each dual-port memory cell of the array of dual-port memory cells is configured as:
a dual-port memory cell in response to the first driver circuit being enabled, or
a single port memory cell in response to the second driver circuit being enabled.

5. The memory circuit of claim 4, further comprising:
a first set of conductors extending in a first direction, and being coupled to the memory cell array;
a second set of conductors extending in the first direction, and being coupled to the memory cell array;
a third set of conductors extending in a second direction, and being coupled to the memory cell array, the second direction being different from the first direction;
a fourth set of conductors extending in the second direction, and being coupled to the memory cell array.
a fifth set of conductors extending in the first direction, and being coupled to the memory cell array; and
a sixth set of conductors extending in the second direction, and being coupled to the memory cell array.

6. The memory circuit of claim 5, wherein each dual-port memory cell of the array of dual-port memory cells comprises:
a first inverter coupled to a first storage node;
a second inverter coupled to a second storage node and the first inverter;
a first pass gate transistor coupled to a first conductor of the third set of conductors, the first storage node, the first inverter, and a first conductor of the fifth set of conductors;
a second pass gate transistor coupled to a first conductor of the fourth set of conductors, the second storage node, the second inverter, and the first conductor of the fifth set of conductors;
a third pass gate transistor coupled to a first conductor of the first set of conductors, the second inverter and a first conductor of the sixth set of conductors; and
a fourth pass gate transistor coupled to a first conductor of the second set of conductors, the first inverter and the first conductor of the sixth set of conductors.

7. The memory circuit of claim 6, wherein
each dual-port memory cell of the array of dual-port memory cells is configured as the dual-port memory cell in response to the first driver circuit being enabled;
the first conductor of the first set of conductors is configured as a write bit line;
the first conductor of the second set of conductors is configured as a write bit line bar;
the first conductor of the third set of conductors is configured as a read bit line bar;
the first conductor of the fourth set of conductors is configured as a read bit line;
the first conductor of the fifth set of conductors is configured as a read word line; and
the first conductor of the sixth set of conductors is configured as a write word line.

8. The memory circuit of claim 6, wherein
each dual-port memory cell of the array of dual-port memory cells is configured as the single port memory cell in response to the second driver circuit being enabled;
the first conductor of the third set of conductors is configured as a read bit line bar or a write bit line bar;
the first conductor of the fourth set of conductors is configured as a read bit line or a write bit line; and
the first conductor of the fifth set of conductors is configured as a read word line or a write read word line.

9. The memory circuit of claim 1, wherein
the first driver circuit is configured to write the second set of weight signals to the memory cell array in a first direction, and
the second driver circuit is configured to write the first set of weight signals to the memory cell array in a second direction different from the first direction.

10. A memory circuit, comprising:
a first memory cell array configured to store a first set of weight signals or a second set of weight signals, the second set of weight signals being transposed with respect to the first set of weight signals;
a first multiply-accumulate (MAC) circuit coupled to the first memory cell array, and configured to generate a first set of data in response to a first set of input data and one of the first set of weight signals or the second set of weight signals;
a first driver circuit coupled to the first memory cell array, and configured to write the second set of weight signals to the first memory cell array in response to being enabled by a first enable signal, the first driver circuit being configured to be enabled or disabled in response to the first enable signal;
a second driver circuit coupled to the first memory cell array, and configured to write the first set of weight signals to the first memory cell array in response to being enabled by a second enable signal, the second enable signal being inverted from the first enable signal, the second driver circuit being configured to be enabled or disabled in response to the second enable signal; and
a read circuit coupled to the first memory cell array and the first MAC circuit, and configured to read the first memory cell array in response to being enabled by a third enable signal.

11. The memory circuit of claim 10, wherein the first driver circuit comprises:
a first circuit coupled to the first memory cell array, and the first circuit comprising:
a first input terminal of the first circuit configured to receive the first set of weight signals;
a first output terminal of the first circuit configured to output the second set of weight signals in response to being enabled; and
a first voltage supply node; and
a first transistor coupled between the first voltage supply node of the first circuit and a first voltage supply.

12. The memory circuit of claim 11, wherein the first transistor comprises:
a first source of the first transistor coupled to the first voltage supply;
a first gate of the first transistor configured to receive the first enable signal; and
a first drain of the first transistor coupled with the first voltage supply node of the first circuit.

13. The memory circuit of claim 12, wherein the second driver circuit comprises:
a second circuit coupled to the first memory cell array, and the second circuit comprising:
a first input terminal of the second circuit configured to receive the first set of weight signals;
a first output terminal of the second circuit configured to output the first set of weight signals in response to being enabled; and
a second voltage supply node; and
a second transistor coupled between the second voltage supply node of the second circuit and the first voltage supply.

14. The memory circuit of claim 13, wherein the second transistor comprises:
a first source of the second transistor coupled to the first voltage supply;
a first gate of the second transistor configured to receive the second enable signal; and
a first drain of the second transistor coupled with the first voltage supply node of the second circuit.

15. The memory circuit of claim 10, further comprising:
a second memory cell array configured to store a third set of weight signals or a fourth set of weight signals, the fourth set of weight signals being transposed with respect to the third set of weight signals;
a second MAC circuit coupled to the second memory cell array, and configured to generate a second set of data in response to a second set of input data and one of the third set of weight signals or the fourth set of weight signals;
wherein the first driver circuit is further coupled to the second memory cell array, and is further configured to write the fourth set of weight signals to the second memory cell array in response to being enabled by the first enable signal; and
a second driver circuit is further coupled to the second memory cell array, and is further configured to write the third set of weight signals to the second memory cell array in response to being enabled by the second enable signal.

16. The memory circuit of claim 15, wherein
the first driver circuit is configured to write the second set of weight signals or the fourth set of weight signals to the corresponding first or second memory cell array in a first direction;
the second driver circuit is configured to write the first set of weight signals or the third set of weight signals to the corresponding first or second memory cell array in a second direction different from the first direction; and
the read circuit configured to read the first memory cell array and the second memory cell array in the second direction.

17. The memory circuit of claim 15, wherein the read circuit is further coupled to the second memory cell array and the second MAC circuit, and is further configured to read the second memory cell array in response to being enabled by the third enable signal.

18. The memory circuit of claim 15, further comprising:
an adder circuit coupled to the first MAC circuit and the second MAC circuit, and configured to generate a first set of output signals in response to the first set of data and the second set of data.

19. A method of operating a memory circuit, the method comprising:
receiving, by a first driver circuit and a second driver circuit, a first set of weight signals;
receiving, by the first driver circuit, a first enable signal, the first driver circuit being configured to be enabled or disabled in response to the first enable signal;
receiving, by the second driver circuit, a second enable signal, the second driver circuit being configured to be enabled or disabled in response to the second enable signal, the second enable signal being inverted from the first enable signal;
configuring a first memory cell in a memory cell array as a multi-port memory cell or a single port memory cell in response to the first enable signal and the second enable signal;
performing a write operation of the memory cell array, the performing the write operation of the memory cell array comprising:
writing, by the first driver circuit, a second set of weight signals in response to the first enable signal, or
writing, by the second driver circuit, the first set of weight signals in response to the second enable signal, the second set of weight signals being transposed with respect to the first set of weight signals; and
performing, by a read circuit, a read operation of the memory cell array in response to being enabled by a third enable signal.

20. The method of claim 19, wherein
writing, by the first driver circuit, the second set of weight signals in response to the first enable signal, comprises:
writing, by the first driver circuit, the second set of weight signals to the memory cell array in a first direction;
writing, by the second driver circuit, the first set of weight signals in response to the second enable signal, comprises:
writing, by the second driver circuit, the first set of weight signals to the memory cell array in a second direction different from the first direction; and
wherein performing, by the read circuit, the read operation of the memory cell array in response to being enabled by the third enable signal comprises:
reading the memory cell array in the second direction.
